(19) United States
(12) Patent Application Publication
(10) Pub. No.: US 2021/0315121 A1
(43) Pub. Date: Oct. 7, 2021

(54) TRANSCEIVER LATCH AND THERMAL BRIDGE

(71) Applicant: SAMTEC, INC., New Albany, IN (US)

(72) Inventors: R. Brad BETTMAN, Mountain View, CA (US); Josue Alfredo CARMONA ARAYA, New Albany, IN (US); John Lawrence NIGHTINGALE, Portola Valley, CA (US); Jean Karlo WILLIAMS BARNETT, New Albany, IN (US); Eric ZBINDEN, Santa Clara, CA (US)

(21) Appl. No.: 17/265,413

(22) PCT Filed: Aug. 2, 2019
(86) PCT No.: PCT/US2019/044773

§ 371 Date: Feb. 2, 2021

Related U.S. Application Data
(60) Provisional application No. 62/713,608, filed on Aug. 2, 2018.

(51) Int. Cl. H05K 7/14; H05K 7/20

(52) U.S. Cl. CPC H05K 7/1405; H05K 7/2039

(57) ABSTRACT

A variety of methods and arrangements for latching a transceiver to a host printed circuit board (PCB) are described. The transceiver is secured to its electrical sockets by a latch that does not extend or only minimally extends beyond the transceiver footprint and height. In some embodiments the latch includes a thermal bridge that provides a heat transfer path between the transceiver and host substrate.

### CROSS-REFERENCE TO RELATED APPLICATIONS

This claims priority to U.S. Patent Application Ser. No. 62/713,608 filed Aug. 2, 2018, the disclosure of which is hereby incorporated by reference as if set forth in its entirety herein.

### BACKGROUND

Interconnect systems can include a transceiver that can include an optical engine, and a cable connected to the optical engine. The cable can include one or more fiber optic cables, copper cables, or a combination of the two. The transceiver can include a transceiver printed circuit board (PCB) and the optical engine can be mounted onto the transceiver PCB. The optical engine is configured to receive optical signals from the cable, and convert the optical signals to electrical signals. Further, the optical engine is configured to receive electrical signals, convert the electrical signals to optical signals, and transmit the optical signals along the cables. The interconnect substrate can include an IC chip that is configured to route and/or modify the electrical signals transmitted to and from the transceiver, including conditioning the electrical signals for protocol specific data transfers.

Interconnect systems can further include an electrical connector system including first and second electrical connectors that are mounted onto a host substrate. The first electrical connector can be disposed forward of the second electrical connector, and can thus be referred to as a front electrical connector. The second electrical connector can be referred to as a rear electrical connector. Further, the front electrical connector can be configured to route data signals at higher speeds than the second electrical connector. For instance, the first electrical connector can be configured to transmit electrical signals at data transfer speeds of at least 10 Gigabits per second. Electrical power can also be routed to the second electrical connector.

Each of the electrical connectors includes a respective connector housing and electrical contacts supported by the connector housing. The transceiver is configured to mate with the first and second electrical connectors. For instance, the front end of the interconnect substrate can be inserted along a forward direction into a receptacle of the first electrical connector so as to establish an electrical connection between the interconnect substrate and the electrical contacts of the first electrical connector. The electrical contacts of the second electrical connector can be configured as compression contacts, such that the interconnect PCB can be brought down onto the contacts so as to compress against them and mate the transceiver with the second electrical connector. Thus, the second electrical connector can be referred to as an electrical compression connector.

During operation, optical signals received by the interconnect module from the cable are converted to electrical signals. Ones of the electrical signals can be routed to the first electrical connector, while others of the electrical signals can be routed to the second electrical connector. For instance, high speed electrical signals can be routed to the first electrical connector, and low speed electrical signals can be routed to the second electrical connector. Conversely, electrical signals received by the interconnect module from the first and second electrical connectors are converted into optical signals and output along the optical cables. Of course, in embodiments whereby the cable includes electrically conductive cables, the interconnect module is configured to receive electrical signals from the electrically conductive cables, and transmit electrical signals to the cable. Various ones of the electrical signals can be routed to the first electrical connector, and various others of the electrical signals can be routed to the second electrical connector. Of course, if the cable includes only electrical cables, the transceiver could be provided without the optical engine.

### SUMMARY

In one aspect of the present disclosure, a latch can be configured to secure a daughter substrate to a host module having first and second electrical connectors that are mounted on a host substrate. The latch can include a latch body having a latch base and a latch finger that is supported by the latch base. The latch can be sized to fit between the daughter substrate and host substrate, such that the latch finger engages a corresponding latch engagement member of at least one of the daughter substrate and the host substrate to secure the daughter substrate to the host module after the daughter substrate has been mated to the first and second electrical connectors.

### BRIEF DESCRIPTION OF DRAWINGS

FIG. 1A is a schematic side elevation view of an interconnect system including a host module, an interconnect module shown partially inserted into the host module, and a latch configured to secure the interconnect module to the host module;

FIG. 1B is a schematic side elevation view of the interconnect system illustrated in FIG. 1A, but showing the interconnect substrate fully inserted into the host module so as to mate with front and rear electrical connectors of the host module;

FIG. 2 is a top plan view of the interconnect substrate illustrated in FIG. 1A:

FIG. 3 is a perspective view of the interconnect system illustrated in FIG. 1B;

FIG. 4A is a schematic side elevation view of the interconnect system showing a minimum distance between a shoulder of the interconnect substrate and the rear electrical connector of the host module;

FIG. 4B is a schematic side elevation view similar to FIG. 4A, but showing a maximum distance between the shoulder and the rear electrical connector;

FIG. 5 is a sectional side elevation view of the interconnect system showing a latch engaged in an aperture of a host substrate of the host module;

FIG. 6 is a perspective view of the latch illustrated in FIG. 5;

FIG. 7 is a schematic perspective view of a latch constructed in accordance with another example;

FIG. 8A is a schematic top plan view of a latch configured to attach to an electrical connector in another example;

FIG. 8B is a schematic top plan view of a latch similar to FIG. 8A, but configured to attach to an electrical connector in still another example;

FIG. 9 is a perspective view of the host module showing the latch disposed between the front and rear connectors prior to installation of the transceiver;

FIG. 10 is a perspective view of a latch constructed in accordance with yet another example; wherein the latch is configured for insertion after the interconnect substrate has been mated with the front and rear connectors of the host module;

FIG. 11 is a perspective view of a latch constructed in accordance with still another example, wherein the latch is configured for insertion after the interconnect substrate has been mated with the front and rear connectors of the host module;

FIG. 12A is a perspective view of a tool configured to assist in at least one of the insertion and removal of the interconnect module into and out of mating engagement with the host module illustrated in FIG. 1A;

FIG. 12B is a front elevation view of the tool illustrated in FIG. 12A;

FIG. 12C is a rear elevation view of the tool illustrated in FIG. 12A;

FIG. 12D is a left elevation view of the tool illustrated in FIG. 12A;

FIG. 12E is a right elevation view of the tool illustrated in FIG. 12A;

FIG. 12F is a top plan view of the tool illustrated in FIG. 12A;

FIG. 12G is a bottom plan view of the tool illustrated in FIG. 12A;

FIG. 13A is a side elevation view of the interconnect system illustrated in FIG. 1 shown including the tool during operation;

FIG. 13B is a side elevation view of the interconnect system illustrated in FIG. 13A, including a latch;

FIG. 14 is a sectional side elevation view of the interconnect system showing a thermal bridge disposed between the interconnect substrate and the host substrate;

FIG. 15 is a side elevation view of a thermal bridge that encloses an elastic thermal pad;

FIG. 16 is a side elevation view showing a thermal bridge in accordance with another example, shown configured as an O-shaped spring clip;

FIG. 17 is a side elevation view showing a thermal bridge in accordance with another example, shown configured as a C-shaped spring clip;

FIG. 18A is a perspective view of an O-shaped spring clip having an outer sheath and inner stiffener;

FIG. 18B is a schematic elevation view showing the spring clip both in its compressed state and uncompressed or “free” state;

FIG. 19 is a side elevation view of a thermal bridge including elastic thermal gap pads in another example;

FIG. 20A is a perspective view showing a thermal bridge formed from a coil spring assembly in accordance with another example;

FIG. 20B illustrates a method of making the thermal bridge of FIG. 20A;

FIG. 21A is a sectional side elevation view of a canted coil spring assembly in another example, shown in its decompressed state;

FIG. 21B is a sectional side elevation view of the canted coil spring assembly of FIG. 21A, shown in its compressed state;

FIG. 22A is a top plan view of a plurality of canted coil springs mounted onto a thermal support body;

FIG. 22B is a sectional side elevation view of one of the canted coil springs mounted onto the thermal support body as illustrated in FIG. 22A;

FIG. 23A is a perspective view of a linear canted coil with a side insertion latch;

FIG. 23B is a top plan view of the linear canted coil illustrated in FIG. 23A;

FIG. 23C is a front elevation view of the linear canted coil illustrated in FIG. 23A;

FIG. 23D is a side elevation view of the linear canted coil illustrated in FIG. 23A;

FIG. 24A is a perspective view of a linear canted coil thermal bridge integrated into the latch illustrated in FIG. 6 in one example;

FIG. 24B is a top plan view of the linear canted coil illustrated in FIG. 24A;

FIG. 24C is a front elevation view of the linear canted coil illustrated in FIG. 24A;

FIG. 24D is a side elevation view of the linear canted coil illustrated in FIG. 24A;

FIG. 25A is a perspective view of a linear canted coil thermal bridge integrated in the latch of FIG. 7 in another example;

FIG. 25B is a top plan view of the linear canted coil illustrated in FIG. 25A;

FIG. 25C is a front elevation view of the linear canted coil illustrated in FIG. 25A;

FIG. 25D is a side elevation view of the linear canted coil illustrated in FIG. 25A;

FIG. 26 is a top plan view of a circular canted coil spring;

FIG. 27 is a side elevation view showing a thermal support body that surrounds a circular canted coil spring;

FIG. 28 is a side elevation view showing a thermal support body internal to a circular canted coil spring;

FIG. 29A is a perspective view of a latch having an integrated thermal bridge;

FIG. 29B is a top plan view of the latch illustrated in FIG. 29A;

FIG. 29C is a front elevation view of the latch illustrated in FIG. 29A;

FIG. 29D is a side elevation view of the latch illustrated in FIG. 29A;

FIG. 29E is a perspective view of a host module including the latch of FIGS. 29A-29D mounted onto the host substrate between the front and rear electrical connectors;

FIG. 30A is a sectional side elevation view of a thermal bridge formed from a single fuzz ball secured in a fuzz ball retainer;

FIG. 30B is a perspective view of the fuzz ball retainer illustrated in FIG. 30A;

FIG. 31 is a sectional side elevation view of a thermal bridge having a cup that surrounds a fuzz ball, showing the fuzz ball in both an uncompressed position and a compressed position;

FIG. 32 is an exploded perspective view of a thermal bridge including a fuzz ball support and a plurality of fuzz balls;

FIG. 33A is a top perspective view of a double-sided fuzz ball support having a plurality of cups, and fuzz balls disposed in respective ones of the cups;

FIG. 33B is a bottom perspective view of the double-sided fuzz ball support illustrated in FIG. 33A, having a plurality of cups, and fuzz balls disposed in respective ones of the cups;

FIG. 34A is a sectional side elevation view of a fuzz ball retainer illustrating fuzz ball retention cups constructed in accordance with various alternative examples; and

FIG. 34B is a sectional side elevation view of a fuzz ball retainer illustrating fuzz ball retention cups constructed in accordance with still other various alternative examples.

### DETAILED DESCRIPTION

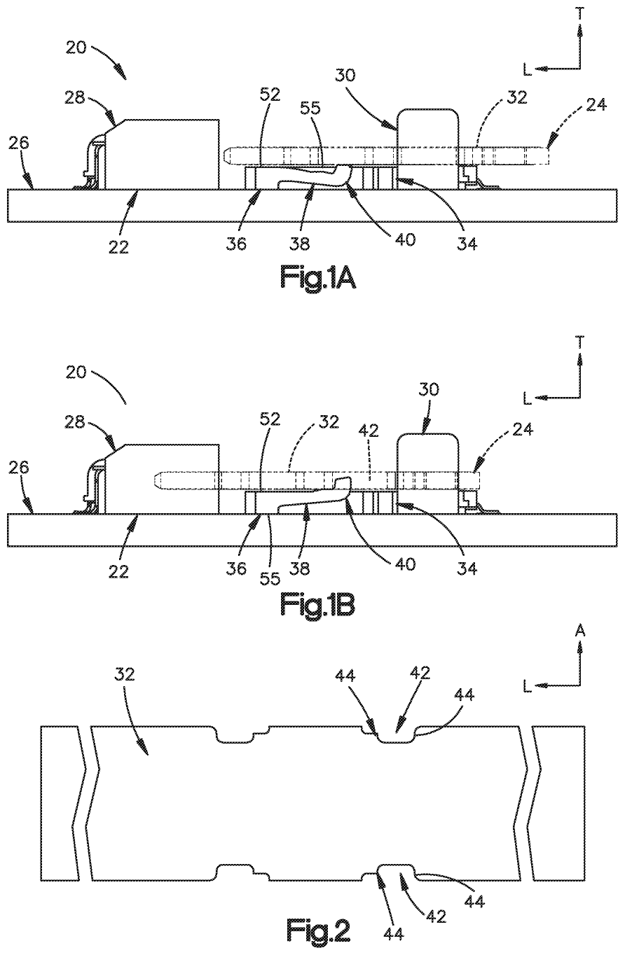

Referring to FIGS. 1A-1B, an interconnect system 20 includes a host module 22 and an interconnect module 24 that is configured to be mated to the host module 22. The host module 22 can include a host substrate 26, a first electrical connector 28 that is configured to be mounted to the host substrate 26, and a second electrical connector 30 that is configured to be mounted to the host substrate 26. The host substrate 26 can be configured as a printed circuit board (PCB). The first electrical connector 28 can be referred to as a front electrical connector, and the second electrical connector 30 can be referred to as a rear electrical connector. In this regard, the first electrical connector 28 can be spaced from the second electrical connector 30 in a forward direction when the first and second electrical connectors 28 and 30 are mounted to the host substrate 26. Conversely, the second electrical connector 30 can be spaced from the first electrical connector 28 in a rearward direction that is opposite the forward direction. The forward direction and rearward direction can each be oriented along a longitudinal direction L. The first electrical connector 28 can be configured to operate at higher data transfer speeds than the second electrical connector 30. The second electrical connector 30 can further be configured to communicate electrical power and control signals.

The interconnect module 24 can be configured as any suitable module that is designed to establish an electrical connection with the first and second electrical connectors 28 and 30. As illustrated in FIGS. 1A-1B, the interconnect module 24 can include an interconnect substrate 32 that is configured to mate with the first and second electrical connectors 28 and 30, thereby mating the interconnect substrate 32, and thus the interconnect module 24, to the host module 22. The host substrate 26 defines a first top surface and a second bottom surface that is opposite the top surface along the transverse direction T. The bottom surface can be said to be spaced from the top surface along the downward direction. Conversely, the top surface can be said to be spaced from the bottom surface along the upward direction. The top surface of the host substrate 26 is configured to face the interconnect substrate 32 when the interconnect substrate 32 is mated with the host module 22. Further, the first and second electrical connectors 28 and 30 can be mounted onto the top surface of the host substrate 26.

The interconnect substrate 32 can similarly define a first top surface and a second bottom surface that is opposite the top surface along the transverse direction. The bottom surface of the interconnect substrate 32 can face the top surface of the host substrate 26 when the interconnect substrate 32 is mated with the host module 22. The interconnect module 24 can further include an optical engine can be disposed on the top surface of the interconnect substrate 32, for instance when the interconnect substrate 32 is configured as an optical transceiver. The bottom surface of the interconnect substrate 32 can be said to be spaced from the top surface of the interconnect substrate 32 along the downward direction. Conversely, the top surface of the interconnect substrate 32 can be said to be spaced from the bottom surface of the interconnect substrate 32 along the upward direction.

In this regard, reference to mating with the first and second electrical connectors can be used interchangeably with mating with the host module 22 or host substrate 26, and vice versa. In one example, the interconnect module 24 can be configured as a transceiver. Thus, the interconnect substrate 32 can also be referred to as a transceiver substrate. In one example, the transceiver can be configured as an optical transceiver. Alternatively or additionally, the transceiver can be configured as an electrical transceiver. In one example, the interconnect module can be a FireFly™ optical transceiver manufactured by Samtec Inc. or a COBO compliant optical transceiver. Thus, the host module 22 can be configured to mate with a FireFly™ optical transceiver manufactured by Samtec Inc. or a COBO compliant optical transceiver. When the host module 22 is configured to mate with the FireFly™ optical transceiver, the first electrical connector 28 can be a UEC5 connector manufactured by Samtec Inc. having a principal place of business in New Albany, Ind., and the rear connector 30 can be a UCC8 connector manufactured by Samtec Inc.

Described herein are apparatus and methods that are configured to secure the interconnect module 24 to the host module 22 when the interconnect module 24 is mated to the host module 22. Also described herein are thermal bridges to provide a low impedance thermal path between the interconnect substrate 32 and the host substrate 26. That is, the thermal path can have a lower impedance than the impedance from the interconnect substrate to the host substrate without the thermal bridge.

As illustrated in FIGS. 1A-1B, when the interconnect module 24 is mated with the host module 22, a gap 34 can be defined between the host substrate 26 and interconnect substrate 32 along a transverse direction T that is oriented perpendicular with respect to the longitudinal direction L. The gap 34 extends along the interconnect substrate 32 and host substrate 26 between the front and rear connectors 28 and 30 along the longitudinal direction L. The gap 34 as measured from the rear connector 30 to a receptacle of the front connector 28 along the longitudinal direction L can be sized as desired. In one example, the gap 34 along the longitudinal direction L can be between approximately 3 mm and approximately 20 mm, such as between approximately 5 mm and approximately 10 mm, such as approximately 9 mm. In still other examples, the gap 34 along the longitudinal direction L can range from approximately 16 mm to approximately 21 mm. The receptacle can be configured to receive a front end of the interconnect substrate 32 so as to mate the interconnect substrate 32, and thus the interconnect module 24, to the first electrical connector 28. The host module 22 and the interconnect module 24 can also extend along a lateral direction A that is perpendicular to each of the transverse direction T and the longitudinal direction L. When the host module 22 and the interconnect module 24 are oriented as illustrated, the transverse direction T can be oriented along a vertical direction and the longitudinal direction L can be oriented along a horizontal direction. Thus, use of the terms “vertical,” “up,” “down,” “top,” “bottom,” or derivatives thereof can refer to the transverse direction T. Similarly, reference to a horizontal direction can apply to one or both of the longitudinal direction L and the lateral direction A. The term “up,” “top,” and derivatives thereof can be defined by a direction from the host substrate 26 to the interconnect substrate 32 when the interconnect substrate 32 has been mated with the host module 22. Conversely, the terms “down,” “lower,” “bottom,” and derivatives thereof can be defined by a direction from the interconnect substrate 32 to the host substrate 26 when the interconnect substrate 32 has been mated with the host module 22.

The interconnect system 20 can include a latch 36 that is disposed in the gap 34. The latch 36 can be configured to secure the host module 22 to the interconnect module 24. The gap 34 can define any suitable vertical distance or height from the bottom of the interconnect substrate 32 and the top of the host substrate 26 as desired. For instance, the height can range from approximately 1 mm to approximately 3 mm. The term “approximate” and “substantial” and derivatives thereof as used herein recognizes that the referenced dimensions, sizes, shapes, directions, or other parameters can include the stated dimensions, sizes, shapes, directions, or other parameters and up to ±20%, including ±10%, ±5%, and ±2% of the stated dimensions, sizes, shapes, directions, or other parameters. It should be appreciated that while vertical distances of the gap 34 have been described above, larger and smaller gaps are possible.

The latch 36 can be disposed on the top surface of the host substrate 26 between the first and second connectors 28 and 30 without securing the latch 36 to any components of the host module 22. Thus, the first and second connectors 28 and 30 can prevent the latch 36 from traveling off the host substrate 26 along the longitudinal direction. When the latch 36 is engaged with the interconnect substrate 32, interference between the interconnect module 24 and the host module 22 can prevent the latch 36 from travelling off of the host substrate 26. In one example, the latch 36 can be attached to the host substrate 26 in any manner desired. The latch 36 can have a latch body 52 that can include a latch base 55 and at least one latch arm 38 that extends out from the latch base 55. The latch base 55 can define a substantially planar top surface and a substantially planar bottom surface opposite the substantially planar top surface. The at least one latch arm 38 can be configured to be displaced with respect to the latch base 55 toward the host substrate 26 as the interconnect substrate 32 is inserted into the host module 22. In one example, the at least one latch arm 38 can be cantilevered from the latch base 55. The latch 36 can further include at least one engagement member such as a latch finger 40 that is supported by the latch base 55. For instance, as described in more detail below, the latch finger 40 can extend out from the latch base 55. In another example, the latch finger 40 can extend out from the latch arm 38 that, in turn, extends out from the latch base 55. In one example, the latch finger 40 can extend out from a distal end of the latch arm 38 that is opposite the latch base 55. In one example, the latch finger 40 can be deflectable. In particular, the latch arm 38 that can be resiliently flexible. The deflectable latch finger 40 can be said to extend out with respect to each of the latch arm 38 and the latch body 52 with respect to the transverse direction T. For instance, the deflectable latch finger 40 can be said to extend out with respect to each of the latch arm 38 and the latch body 52 with respect to the transverse direction T when the latch arm 38 is unflexed. Alternatively, as described in more detail below (see, e.g., FIGS. 10-11), the latch 36 can further include a fixed latch finger 56 that extends out from the latch base 55. The fixed latch finger 56 is positionally fixed with respect to the latch body 52, and thus the latch base 55.

During operation, as the interconnect substrate 32 is pressed forward into the first electrical connector 28, the latch finger 40 can ride along the bottom surface of the interconnect substrate 32. The latch finger 40 can be carried by the latch arm 38. The latch arm 38 can be deflected from a neutral position as the latch finger 40 rides along the bottom surface of the interconnect substrate 32. Thus, when the latch arm 38 is in the deflected position, the latch arm 38 can provide a biasing force that biases the latch finger 40 upward as it rides along the bottom surface of the interconnect substrate 32. When the interconnect substrate 32 is fully inserted into the first connector 28, the resilient flexibility of the latch arm latch arm 38 can cause the latch arm 38 to be displaced upward toward the neutral position, thereby causing the latch finger 40 to correspondingly move upward and engage a complementary latch engagement member of the interconnect substrate 32, thereby securing the interconnect substrate 32 to the latch 36. In one example, the complementary latch engagement member can be configured as a latch aperture 42 of the interconnect substrate 32 that is configured to receive the latch finger 40. The latch finger 40 can thus contact a surface of the interconnect substrate 32 that at least partially defines the latch aperture 42, thereby preventing the interconnect substrate 32 from traveling in a rearward direction, or backing out, a sufficient distance that would cause the interconnect substrate 32 unmate from the host module 22. Thus, the latch finger 40 is deflectable between a closed position and an open position. In the closed position, the latch finger 40 is positioned to be inserted in the latch aperture 42. In the open position, the latch finger 40 is positioned to be removed from the latch aperture 42. Thus, the latch 36 can be releasably secured to the interconnect substrate 32. The latch finger 40 can be naturally biased to the closed position. That is, the latch arm 38 can bias the latch finger 40 to be in the closed position absent an external force that urges the latch finger 40 to the open position. Thus, in one example, the latch arm 38 can drive the latch finger into the latch aperture 42. For instance, the latch arm 38 can be flexible and resilient, such that deflection of the latch arm 38 in the downward direction causes the latch arm 38 to apply a force that biases the latch finger 40 to move in the upward direction. The latch arm 38 can be resiliently deflected downward as the latch finger 40 rides along the bottom surface of the interconnect substrate 32.

In one example, with reference now to FIG. 2, the latch aperture 42 of the interconnect substrate 32 can be defined by a notch 44 of the interconnect substrate 32. In particular, the notch 44 can extend into one of the sides of the interconnect substrate 32 along the lateral direction A. The sides of the interconnect substrate 32 can be opposite each other along the lateral direction A. The notch 44 can further extend through the interconnect substrate 32 along the transverse direction T. The notch 44 can be brought into alignment with the finger 40 on the latch arm 38 along the transverse direction T. Thus, when the latch arm 38 moves upward, the finger 40 is inserted into the notch 44. Thus, the latch finger 40 can contact a surface of the interconnect substrate 32 that at least partially defines the notch 44, thereby preventing the interconnect substrate 32 from traveling in a rearward direction, or backing out, a sufficient distance that would cause the interconnect substrate 32 unmate from the host module 22. This can ensure that electrical continuity is maintained between all of the contacts on both connectors with their respective traces on the host substrate 26. It should be appreciated that the latch aperture 42 can alternatively be an enclosed through hole that extends through the interconnect substrate 32 along the transverse direction at a location spaced from each of the sides of the interconnect substrate 32. In this, regard, the latch aperture 42 can be any suitable void that is configured to receive the latch finger 40 in the manner described herein.

It should be appreciated that at least a portion of the latch 36 up to an entirety of the latch, and all latches disclosed herein, can be made of a thermally conductive material. Thus, the latch 36 can define a thermal bridge of the type described below that can provide a low impedance thermal conductive path that extends from the interconnect substrate 32 to the host substrate 26 when the interconnect module 24 is secured to the host module 22. The latch 36 can further be resiliently compressible such that the thermally conductive material is in reliable contact with both the interconnect substrate 32 and the host substrate 26 when the interconnect module 24 is mated to the host module 22 as described below. The thermally conductive material can further define a thermally conductive path from interconnect substrate 32 to the host substrate 26.

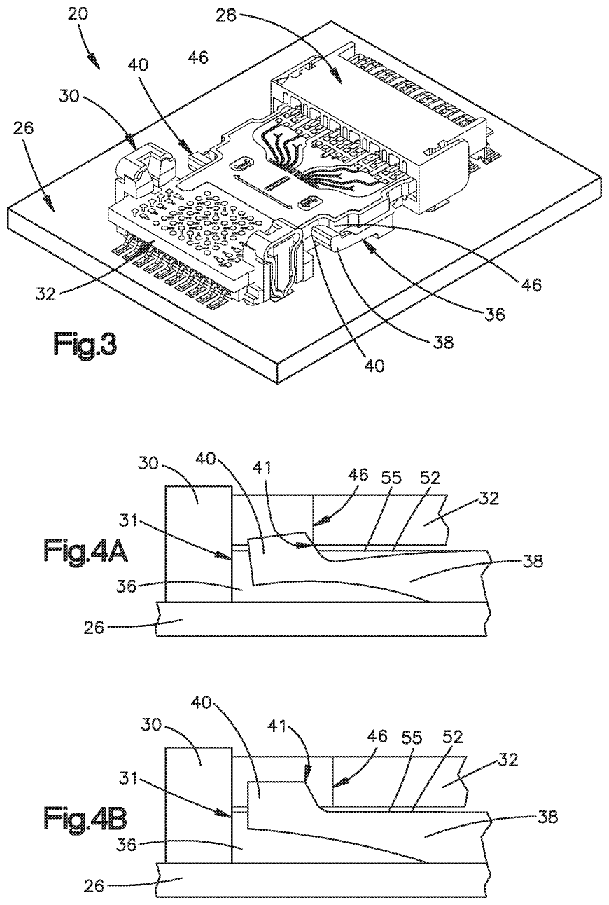

As illustrated in FIGS. 2-3, the interconnect substrate 32 can have two notches on opposed sides of the interconnect substrate 32 with respect to the lateral direction A. The interconnect substrate 32 can further include a shoulder 46 that defines the front end of each notch 44. Similarly, the latch 36 can include a pair of latch arms 38 that extend from the latch base 55. The latch arms 38 can be opposite each other along the lateral direction A. The latch 36 can further include a pair of latch fingers 40 that extend out from the pair of latch arms 38, respectively. Thus, when the interconnect substrate 32 is mated to the host module 22, the latch finger 40 resides in the notch 44 and is wedged between the shoulder 46 and second connector 30. If a force is applied to the interconnect substrate 32 in the rearward direction, attempting to pull the interconnect module 24 out of the first connector 28, the rearward motion is blocked by mechanical engagement between a mating surface 41 of the finger 40 and the shoulder 38, thereby preventing the interconnect substrate 32 from being removed from the first electrical connector 28. More generally the latch fingers 40 can engage with any suitable latch engagement member of the interconnect module, and in particular of the interconnect substrate 32, to secure the interconnect substrate 32 to the host module 22. It should be appreciated that while the interconnect module 24 can be configured as a transceiver in one example, the transceiver components are not illustrated in FIG. 3, in order to clearly show the features of the interconnect substrate 32.

Referring now to FIGS. 4A-4B, it is recognized that manufacturing tolerances can cause some variation in the longitudinal distance between the shoulder 46 of the interconnect substrate 32 and the front face 31 of the second electrical connector 30 when the interconnect module 24 is fully mated with the host module 22, and the latch 36 has secured the interconnect module 24 to the host substrate module. FIG. 4A shows a minimum longitudinal distance between the front face 31 of the second electrical connector 30 and the shoulder 46 (Dₘᵢₙ). When the distance is a minimum, as shown in FIG. 4A, the latch finger 40 can be wedged against the shoulder 46 of the PCB 32. The body of the latch 36 is pressed against the front face 31 of connector 30. There is also a zero gap between the finger 40 and the shoulder 46 and the back of the latch body and both the front face 31 of the second electrical connector 30. Otherwise stated, the latch can contact both the front face 31 of the second electrical connector 30 and the shoulder 46 preventing any rearward travel of the transceiver PCB 32.

FIG. 4B shows a maximum longitudinal distance between the front face 31 of the second electrical connector 30 and the shoulder 46 (Dₘₐₓ). When the distance is a maximum, as shown in FIG. 4B, there is only a small amount of mechanical float, denoted as “max rearward travel,” of the interconnect substrate 32, and thus the interconnect module 24, with respect to the host substrate 26, and thus the host module 22, along the longitudinal direction L. That is, the interconnect substrate 32 can move rearward, and forward. The rearward travel of the interconnect module 24 with respect to the host module 22 can be constrained by mechanical interference between the latch finger 40 and the second electrical connector 30. The forward travel of the interconnect module 24 with respect to the host module 22 can be constrained by mechanical interference between the latch finger 40 and the shoulder 46 of the interconnect substrate 32. The amount of mechanical float may be less than that required to significantly impact the electrical properties of the electrical connections between the interconnect substrate 32 and front and rear connectors 28 and 30. That is, the interconnect substrate 32 can remain mated with the first and second electrical connectors 28 and 30 along an entirety of the mechanical float. The angle of the finger surface can be selected so as to minimize possible interconnect substrate 32 travel in the rearward direction while preventing deflection of the arms and unlatching of the fingers when the transceiver travels rearward. In one example, the mating face 41 can be sloped rearward as it extends upward from the latch arm 38.

Whether the interconnect substrate 32 is able to move in the rearward direction an amount insufficient to cause the interconnect substrate 32 to unmate from either of the first and second electrical connectors 28 and 30 when the latch 36 has engaged the interconnect substrate 32, or whether the interconnect substrate 32 is unable to move in the rearward direction, it can be said that the latch is configured to at least limit movement of the interconnect substrate 32 in the rearward direction. In some examples, the latch 36 can be further configured to prevent movement of the interconnect substrate 32 in the rearward direction.

As described above, the latch 36 may be attached to the host substrate 26. Alternatively, the latch 36 may simply be situated on the host substrate 26 between the front and rear connectors, and unattached to the host substrate 26. Alternatively yet, the latch 36 can be constrained by but unattached to the host substrate 26. FIG. 5 shows one example of the latch 36 secured to the host substrate 26. In this example, the latch 36 can include at least one attachment member that is configured to attach the latch 36 to the host substrate 26. Thus, the latch 36 can be configured to be mounted to the host substrate 26 prior to mating the interconnect substrate with the first and second electrical connectors 28 and 30. The attachment member can be configured as an attachment peg 48 that extends into a respective at least one attachment aperture 50 of the host substrate 26. Thus, the at least one latch finger can extend from one surface of the latch body 52, and the attachment peg 48 can extend from an opposed surface of the latch body 52 along the transverse direction. In one example, the latch 36 can have a plurality of attachment pegs 48, and the host substrate 26 can include a plurality of attachment apertures 50. The attachment apertures 50 can be opposite each other along the lateral direction A. In one example, the latch 36 can include two attachment pegs 48, and the host substrate 26 can include two attachment apertures 50, though any suitable number of attachment pegs 48 and attachment apertures 50 is contemplated. The attachment aperture 50 and corresponding attachment peg 48 can have a variety of cross-sections, such as round, square, rectangular, or any alternative geometry as desired. As described above with respect to the latch apertures, the attachment apertures 50 can be configured as a notch, an enclosed through hole, or any suitable alternative void that is configured to receive the attachment peg in the manner described herein.

In this regard, the latch 36 can include a latch body 52, and the at least one attachment peg 48 can extend out from the latch body 52 along the transverse direction T. Thus, the attachment peg 48 can extend down into the attachment aperture 50. For instance, the attachment peg 48 can extend out from the latch base 55. The latch arm 38 can extend out from the latch base 55 in the manner described above. In particular, the latch arm 38 can extend in the rearward direction from the latch base 55. The latch 36 can be held in place on the host substrate 26 with respect to movement in a plane that is defined by the longitudinal direction L and the lateral direction A. Thus, the latch 36 is constrained with respect to movement along the top surface of the host substrate 26, which is oriented in the plane defined by the longitudinal direction L and the lateral direction A. The latch 36 is movable upward in a direction away from the top surface of the host substrate 26 so as to remove the latch 36 from the host substrate 26. Thus, in one example, the latch 36 can be releasably attached to the host substrate 26. When the latch 36 is attached to the host substrate 26 and latched to the interconnect substrate 32, the interconnect substrate 32 prevents the latch from being moved upward, effectively preventing removal of the latch 36 from the host substrate 26. In another example, the latch 36 can be permanently attached to the host substrate 26 as to prevent removal of the latch 36 from the host substrate 26 without damage to a component or compromising attachment of the latch 36 to the host substrate 26. In one example, the latch 36 can be permanently attached to the host substrate 26 by press-fitting the attachment pegs 48 into the attachment apertures 50, or soldering, epoxying or using any other attachment method to permanently attach the latch 36 to the host substrate 26. In this regard, it should be appreciated that the latch 36 and the host module 22 can include complementary attachment members that are configured to engage each other so as to attach the latch 36 to the host module 22.

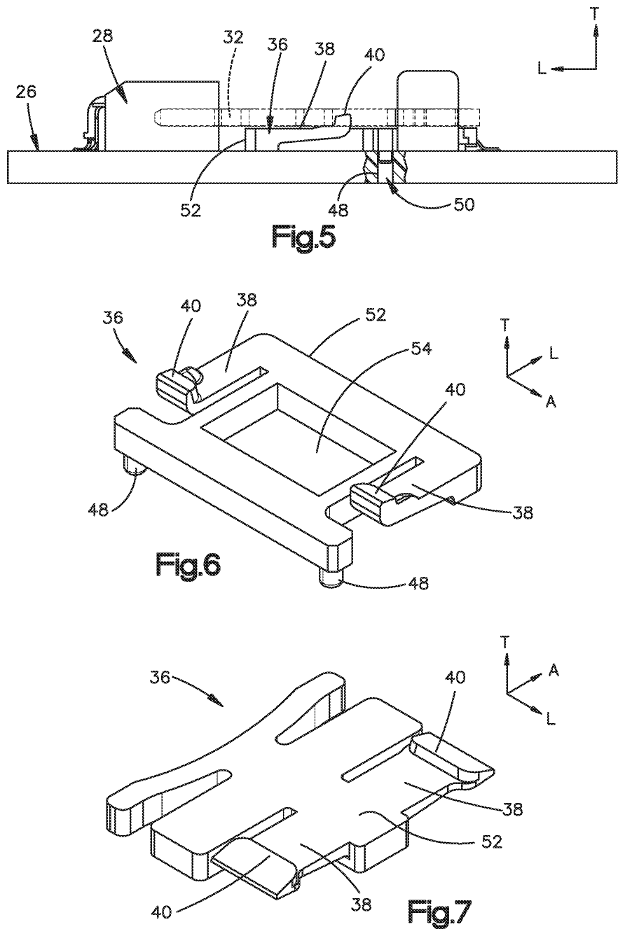

The latch arms 38 may take many forms. FIGS. 6 and 7 illustrate two possible variations of the latch. In FIG. 6, the latch 36 can include first and second latch arms 38 that extend from the latch base 55 substantially along the longitudinal direction L. Thus, the latch arms 38 can extend substantially parallel to each other, and substantially parallel to the insertion direction of the interconnect substrate 32 into the first connector 28 (also referred to herein as the mating direction). Each latch arm 38 can be flexible along the transverse direction T. Otherwise stated, each latch arm 38 can be flexible along a direction that is perpendicular to both the insertion direction and the top surface of the host substrate 26. The latch arms 38 can extend rearward from the latch base 55. The latch 36 can include at least one deflectable latch finger 40 that extends out from a respective at least one latch arm 38, respectively, in the manner described above. For instance, the latch 36 can include first and second latch arms 38 that support respective first and second latch fingers 40. The latch arms 38, and thus the latch fingers 40, can be spaced from each other along the lateral direction A. The latch 36 can have at least one attachment peg 48, such as first and second attachment pegs 48, configured to be inserted into respective attachment apertures 50 to register the latch 36 to with the host substrate 26 prior to mating the interconnect substrate 32 with the host module 22 in the manner described above. The latch fingers 40 can then be inserted into respective latch apertures 42 of the interconnect substrate 32 when the interconnect substrate 32 is mated with the host module 22 in the manner described above. The latch fingers 40 can present a beveled leading surface that is configured to make initial contact with the interconnect substrate 32 as the interconnect substrate 32 is mated with the host module. The beveled leading surface can be angled in the mating direction as it extends in the upward direction. The latch arm 38 can be cantilevered in the mating direction. Alternatively, the latch arm 38 can be cantilevered in a direction opposite the mating direction.

The latch 36 can also be configured to retain a thermal bridge as described in more detail below. In one example, the latch 36 can define a retention aperture 54 that extends therethrough and is configured to retain a thermal bridge. In one example, the retention aperture 54 can extend through the latch body 52 along the transverse direction T. As will be appreciated from the description below, the thermal bridge can provide a low impedance thermal conductive path that extends from the interconnect substrate 32 to the host substrate 26 through the thermal bridge. Alternatively, as described above, the latch 36 can define a thermal bridge.

In another example illustrated in FIG. 7, the latch 36 includes at least one latch arm 38 that extends out from the latch base 55 along the lateral direction A. Thus, the at least one latch arm 38 can extend out from the latch base 55 in a first perpendicular direction that is oriented perpendicular to the mating direction of the interconnect substrate 32. Alternatively or additionally, the at least one latch arm 38 can extend out from the latch base 55 in a second perpendicular direction that is oriented perpendicular to the insertion direction of the interconnect substrate 32, as illustrated in FIG. 7. It should be appreciated, that the at least one latch arm 38 can extend out from the latch base 55 in any suitable direction in a plane that is defined by the longitudinal direction L and the lateral direction A. As illustrated in FIG. 7, the at least one latch arm 38 includes first and second latch arms 38 that are opposite each other along the lateral direction A, and extend away from each other as they extend out from the latch base 55. As described above, the at least one latch arm 38 can be resiliently deflectable in a first direction, which causes the at least one latch arm 38 to apply a spring force that biases the corresponding at least one latch finger 40 in a second direction opposite the first direction. For instance, the at least one latch arm 38 can flex in the first direction. Accordingly, the corresponding at least one latch finger 40 can be biased to ride along the interconnect module 24 as the interconnect substrate 32 is mated with the host module 22. When the at least one latch finger 40 is aligned with the corresponding at least one latch aperture 42 of the interconnect substrate 32 (see FIG. 1B), the spring force of the latch arm 38 can urge the latch finger 40 to move in a second direction opposite the first direction into the latch aperture 42. The at least one latch finger 40 can be aligned with the corresponding at least one latch aperture 42 when the interconnect module 24 is fully mated with the host module 22. That is, the at least one latch finger 40 can be aligned with the corresponding at least one latch aperture 42 when the interconnect substrate 32 is fully inserted into the first electrical connector. Further, the at least one latch finger 40 can be aligned with the corresponding at least one latch aperture 42 when the interconnect substrate 32 is fully mated with each of the first electrical connector 28 and the second electrical connector 30. In this regard, it should be appreciated that the host substrate 26 can define first and second mating regions that are defined by the first and second electrical connectors 28 and 30, respectively.

In one example, the first and second directions can be oriented along the transverse direction T (which can be vertical when the host substrate is horizontally oriented). For instance, the first direction can be defined by the downward direction, and the second direction can be defined by the upward direction. Thus, the at least one latch finger 40 can ride along the bottom surface of the interconnect substrate 32 as the interconnect substrate 32 is inserted into the host module 22. The latch arms 38 can then drive the latch fingers 40 to move in the upward direction into the latch aperture 42 of the interconnect substrate 32 when the latch aperture 42 is aligned with the at least one finger 40 along the transverse direction T, thereby securing the interconnect substrate 32 to the host module 22.

While various examples herein describe the latch 36 as configured to attach to the host substrate 26, and secure to the interconnect substrate 32 once the interconnect substrate 32 has been mated with the first and second electrical connectors 28 and 30, it should be appreciated that the latch 36 can be alternatively be configured to attach to the interconnect substrate 32, and secure to the host substrate 26 once the interconnect substrate 32 has been mated with the first and second electrical connectors 28 and 30. For instance, the latch 36 can be secured to the interconnect substrate 32, and positioned such that the latch arm 38 is displaced upward toward the interconnect substrate 32 as the interconnect substrate 32 is inserted into the host module 22. In particular, as the interconnect substrate 32 is pressed forward into the first electrical connector 28, the latch finger 40 can ride along the top surface of the host substrate 26. When the interconnect substrate 32 is fully mated with the host module 22, the latch arm 38 can be displaced downward, thereby inserting the latch finger 40 into a latch engagement member of the host substrate 26, thereby securing the latch member, and thus securing the interconnect substrate 32, to the host substrate 26. The latch engagement member of the host substrate 26 can be configured as a latch aperture as described above. Thus, the latch aperture of the host substrate 26 can be configured as a notch or an enclosed through-hole. Further, in this example, the first direction can be defined by the upward direction, and the second direction can be defined by the downward direction. In one example, the latch arm 38 can be flexible and resilient, such that deflection of the latch arm 38 in the upward direction causes the latch arm 38 to apply a force that biases the latch finger 40 to move in the downward direction. The latch arm 38 can be resiliently deflected upward as the latch finger 40 rides along the top surface of the host substrate 26. Thus, it can be said that the latch 36 can be configured to attach to one of the host substrate 26 and the interconnect substrate 32, and can be configured to secure to the other of the host substrate 26 and the interconnect substrate 32, thereby securing the interconnect module 24 to the host module 22.

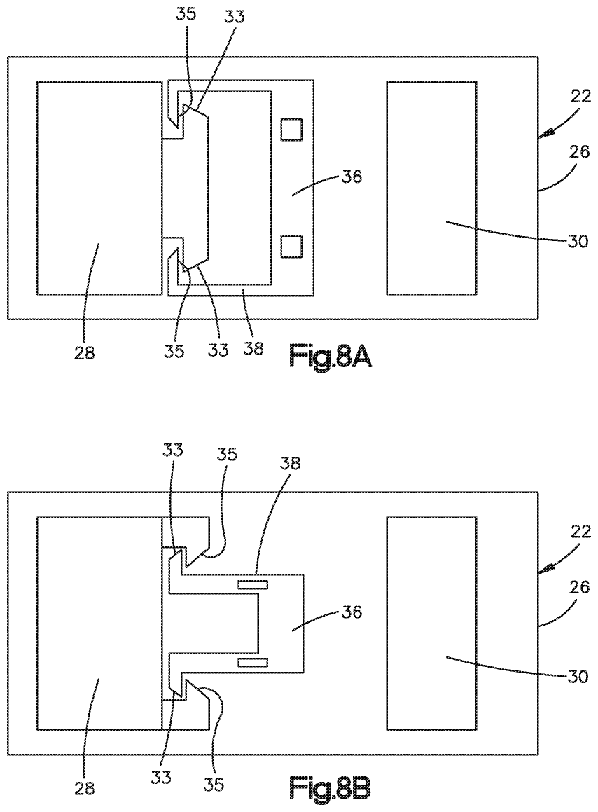

Referring now to FIGS. 8A-8B, it is recognized that the latch 36 can alternatively be configured to be secured to the host module 22. For instance, the latch 36 can be configured to be secured to one of the first and second electrical connectors 28 and 30. In one example, the latch is shown as being secured to the first electrical connector 28. In particular, the latch 36 can include a securement member 33 that is configured to latch onto a complementary securement member 35 of the electrical connector 28. For instance, as illustrated in FIG. 8A, the securement member 35 of the electrical connector 28 can include outer slots that face away from each other receive the securement member 33 of the latch 36. Thus, the securement member 33 can include a pair of latch fingers that are biased toward each other so as to secure in the slots of the securement member 35 of the electrical connector 28. Alternatively, as illustrated in FIG. 8B, the securement member 35 of the electrical connector 28 can include inner slots that face each other and receive the securement member 33 of the latch 36.

The latch 36 and the securement member 35 of the electrical connector 28 can define a position and height along the transverse direction so as to be disposed in the gap between the host substrate 26 and the interconnect substrate when the interconnect substrate is mated with the host module 22. Thus, the securement member 33 can include a pair of latch fingers that are biased away from each other so as to secure in the slots of the securement member 35 of the electrical connector 28. In this regard, it should be appreciated that the latch 36 can be secured to the host module 22 either by securing to the host substrate 26 as described above, or by securing to one of the electrical connectors 28 and 30 of the host module. The latch 36 can further include at least one latch finger 40 as described above so as to secure to the interconnect substrate when the interconnect substrate is mated with the host module 22 as described above.

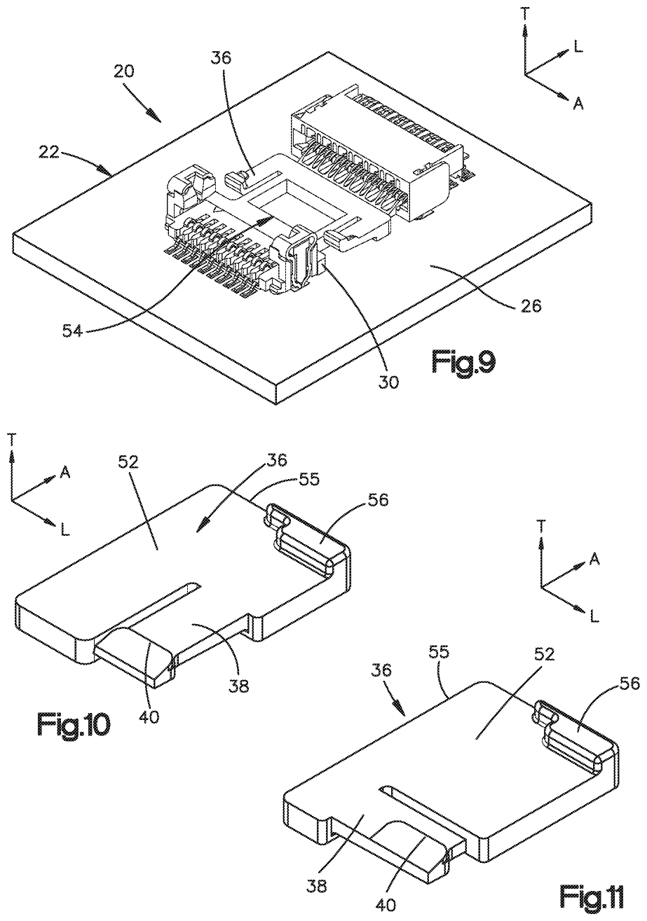

As illustrated in FIG. 9, the latch 36 can be disposed on the top surface of the host substrate 26 between the front and rear electrical connectors 28 and 30 without attaching the latch 36 to the host substrate 26 or the interconnect substrate 32. Mechanical interference between the latch 36 and the first electrical connector 28 can prevent or limit movement of the latch 36 in the forward direction with respect to the host substrate 26. Mechanical interference between the latch 36 and the second electrical connector 30 can prevent or limit movement of the latch 36 in the rearward direction with respect to the host substrate 26. Accordingly, it can be said that the latch 36 is compression fit between the front and rear electrical connectors 28 and 30. When the interconnect substrate 32 (not shown in FIG. 9) is mated with the first electrical connector 28, the latch fingers 40 can be inserted into the latch apertures 42 of the interconnect substrate 32 so as to secure the latch 36 to the interconnect substrate 32 (see FIG. 1B). Thus movement of the latch 36 along the lateral direction A with respect to the host substrate 26 is prevented or limited by interference between the latch 36 and the interconnect substrate 32. Movement of the latch 36 along the transverse direction T with respect to the host substrate 26 is prevented or limited by mechanical interference between the latch 36 and each of the host substrate 26 and the interconnect substrate 32.

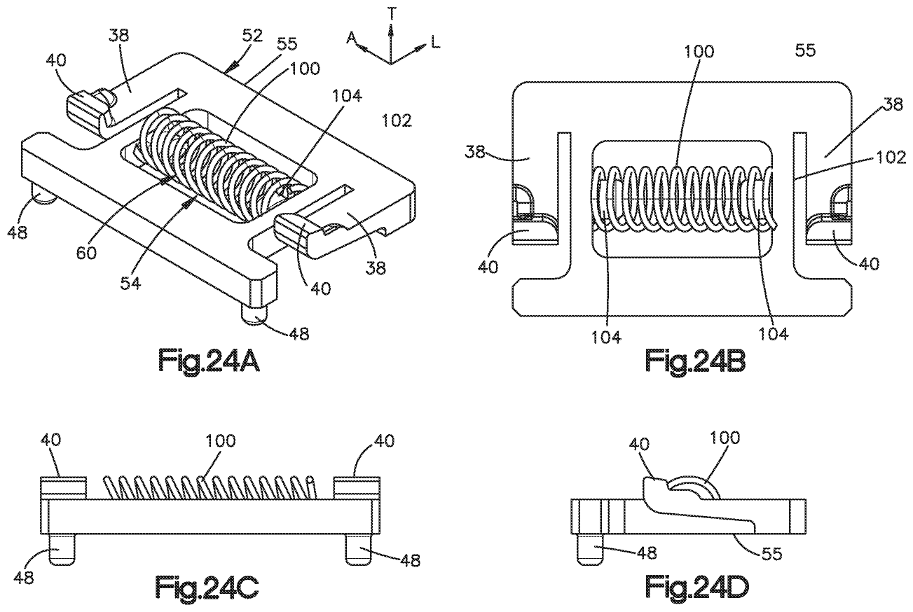

As described above, in some examples the latch 36 can be placed between the first and second electrical connectors 28 and 30 prior to mating of the interconnect substrate 32 with the host module 22. In other examples, the latch 36 may be placed between the interconnect substrate 32 and host substrate 26 after the interconnect substrate 32 has been mated with the first and second electrical connectors 28 and 30. Because these latches 36 are inserted between the interconnect substrate 32 and the host substrate 26 along the lateral direction A, these latches can be referred to as side insertion latches. During operation, the interconnect substrate 32 can be mated with the host module 22. Next, the latch 36 can be inserted between the host substrate 26 and the interconnect substrate 32 so as to at least limit travel of the interconnect substrate 32 in the rearward direction with respect to the host module 22, thereby securing the interconnect substrate 32 to the host module 22. For instance, as illustrated in FIG. 10, the latch 36 can have at least one deflectable latch arm 38 and the deflectable latch finger 40 that extends from the flexible arm 38, in the manner descried above. However, the latch arm 38 can be cantilevered from the latch base 55 along the lateral direction A. The latch 36 can further include at least one fixed finger 56 that extends from the latch base 55. The fixed finger 56 can be disposed opposite the deflectable latch finger 40 along the lateral direction A. The fixed finger 56 is configured to remain substantially stationary, and thus to not deflect along the transverse direction T. In this regard, the latch base 55 can be constructed so as to be substantially rigid and thus substantially not deflectable along the transverse direction T. Further, the fixed finger 56 can be configured to remain substantially stationary along the horizontal direction. Thus, the latch 36 can include first and second latch fingers opposite each other along the lateral direction A. One of the first and second latch fingers can be defined by the deflectable latch finger 40, and the other of the first and second latch fingers can be defined by the fixed finger 56. The deformable latch finger 40 can extend from the latch arm 38. The fixed finger 56 can extend from the latch base 55. Alternatively, as will be described in more detail below (see e.g., FIG. 24A) each of the first and second latch fingers can be defined by the deflectable latch finger 40.

During operation, the interconnect substrate 32 is first mated with the first and second electrical connectors 28 and 30 in the manner described above. The latch 36 can then be positioned between the interconnect substrate 32 and the host substrate 26 at a location between the first and second electrical connectors 28 and 30. In particular, the latch 36 can be moved substantially along the lateral direction A between the host substrate 26 and the interconnect substrate 32. In one example, the latch 36 can be moved in a lateral direction A that is substantially the same direction as the latch arm 38 is cantilevered from the latch body 52 so as to position the latch finger 40 to engage the latch aperture 42 (see FIG. 1B). The movement can be purely in the lateral direction A, or can also include movement along the longitudinal direction L so as to position the latch finger 40 to engage the latch aperture 42. Driving the latch 36 along the lateral direction A can cause the latch arm 38 to flex in the first direction in the manner described above. Accordingly, when the first direction is the downward direction, the latch finger 40 can ride along the bottom surface of the interconnect substrate 32. When the latch finger 40 moves to a position aligned with the latch aperture 42 of the interconnect substrate 32, the latch finger 40 can be driven up into the latch aperture 42. Alternatively, when the first direction is the upward direction, the latch finger 40 can ride along the top surface of the host substrate 26. When the latch finger 40 moves to a position aligned with the latch aperture 42 of the host substrate 26, the latch finger 40 can be driven down into the latch aperture of the host substrate 26. As the deflectable latch finger 40 is moved to a position aligned with the latch aperture, the fixed finger 56 can move into one of the notches 44. In one example, the latch 36 can include first and second fixed fingers 56 that are spaced from each other along the longitudinal direction L. Each of the first and second fixed fingers 56 can be inserted into a respective one of the notches 44 along the lateral direction A when the deflectable latch finger 40 is aligned with the respective latch aperture 42.

In another example, the at least one fixed finger 56 can be replaced by at least one deflectable latch finger 40 that extends from a cantilevered latch arm 38 in the manner described above. Thus, each of the latch fingers 40 can deflect in the first direction. Accordingly, when the first direction is the downward direction, the latch finger 40 can ride along the bottom surface of the interconnect substrate 32. When the latch fingers 40 move to a position aligned with respective ones of the latch apertures 42 of the interconnect substrate 32, the latch fingers 40 can be driven up into the respective latch apertures 42. Alternatively, when the first direction is the upward direction, the latch fingers 40 can ride along the top surface of the host substrate 26. When the latch fingers 40 move to a position aligned with respective ones of the latch apertures of the host substrate 26, the latch fingers 40 can be driven down into the respective latch apertures of the host substrate 26. One or more of the latch arms 38 can be cantilevered along the lateral direction A. Alternatively, one or more others of the latch arms 38 can be cantilevered along the longitudinal direction L.

Thus, it can be said that the latch 36 can be driven along the lateral direction A between the host substrate 26 and the interconnect substrate 32 until a first latch finger is aligned with a respective one of a plurality of latch apertures. The first latch finger can be defined by a deflectable latch finger 40. Once the first latch finger is aligned with the respective one of the plurality of latch apertures, one or more other latch fingers can also be driven into respective ones of one or more other latch apertures. The latch apertures can be defined by one or more notches of the type described above. Alternatively, the latch apertures can be defined by enclosed through-holes. The latch apertures can be defined by one or both of the host substrate 26 and the interconnect substrate 32. Thus, one or more of the latch fingers 40 can extend up from the respective latch arm 38. Alternatively or additionally, one or more of the latch fingers 40 can extend down from the respective latch arm 38. Similarly, one or more of the fixed fingers 56, if present, can extend up from the latch body 52 so as to be driven into notches 44 of the host module in the manner described above. Alternatively or additionally, one or more of the fixed fingers 56 can extend down from the latch base 55 so as to be driven into notches of the interconnect substrate 32 as desired.

It is contemplated that the latch 36 can be constructed in accordance with numerous examples so as to operate in the manner described herein. For instance, in one example illustrated in FIG. 11, the latch arm 38 can be oriented substantially along the longitudinal direction L. In one example, when the latch 36 is placed between the interconnect substrate 32 and the host substrate 26, at least one or more of the latch fingers can be disposed adjacent the front face 31 of the second electrical connector 30.

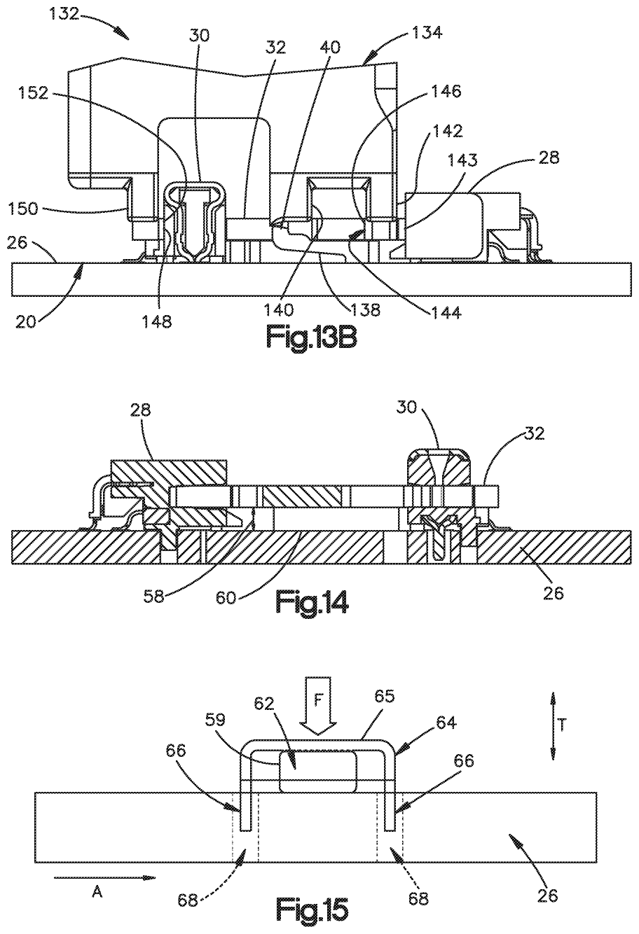

Referring now to FIGS. 13A-13B, an interconnect assembly 132 can include one or both of the host module 22, the interconnect module 24, and an actuator tool 134. The actuator tool 134 can be configured to apply an insertion force to the interconnect substrate 32 so as to cause the interconnect substrate 32 to mate with the electrical connector 28. In this regard, the actuator tool 134 can further cause the interconnect substrate 32 to mate with the electrical connector 30. Alternatively or additionally, the actuator tool 134 can be configured to apply a removal force to the interconnect substrate 32 so as to cause the interconnect substrate 32 to unmate from the electrical connectors 28 and 30. Further, the actuator tool 134 can deflect the deflectable latch finger 40 from the closed position to the open position. In particular, or the embodiments shown in FIGS. 1A-1B, and 3-8, the actuator tool 134 can depress the deflectable latch fingers 40 simultaneously to the open position, such that the latch fingers 40 are removed from the respective latch apertures 42 of the interconnect substrate 32 The interconnect substrate 32 may then be moved in the rearward direction, thereby unmating it from at least the first electrical connector 28. For instance, the interconnect substrate 32 may then be moved in the rearward direction, thereby unmating it from the first and second electrical connectors 28 and 30.

If the latch 36 includes a single deflectable finger 40 and the fixed finger 56 described above, the actuator tool 134 can depress the single deflectable latch finger 40 so as to urge the single deflectable latch finger 40 to the open position. The latch 36 may then be removed out from between the host substrate 26 and interconnect substrate 32 in a removal direction. The removal direction can be defined substantially along lateral direction A. In one example, the removal direction can be defined by a direction from side of the latch having the deflectable latch finger 40 to the side of the latch 36 having the fixed latch finger 56. In this regard, it should be appreciated that the removal direction can be angled with respect to the lateral direction A. Once the latch 36 has been removed, the interconnect substrate 32 can be moved in the rearward direction so as to unmate the interconnect substrate from at least the first electrical connector 28. Rearward movement of the interconnect substrate 32 can be achieved by pulling it out in a substantially longitudinal direction L.

Thus, it can be said that the actuator tool 134 can be configured to urge at least one deflectable latch finger 40 to the open position so as to remove the at least one latch finger 40 from the respective at least one latch aperture 42 of the interconnect substrate 32. Alternatively or additionally, the actuator tool 134 can be configured to apply a rearward force to the interconnect module 24 that urges the interconnect module 24 to move in the rearward direction, thereby unmating the interconnect substrate 32 from the electrical connectors 28 and 30. For instance, the actuator tool 134 can apply the rearward force to the interconnect substrate 32. Alternatively or additionally still, the actuator tool 134 can apply a forward force to the interconnect module 24 that urges the interconnect module 24 to move in the forward direction, thereby mating the interconnect substrate 32 to the first the electrical connector 28 alone or in combination with the second electrical connector 30. For instance, the actuator tool 134 can apply the forward force to the interconnect substrate 32.

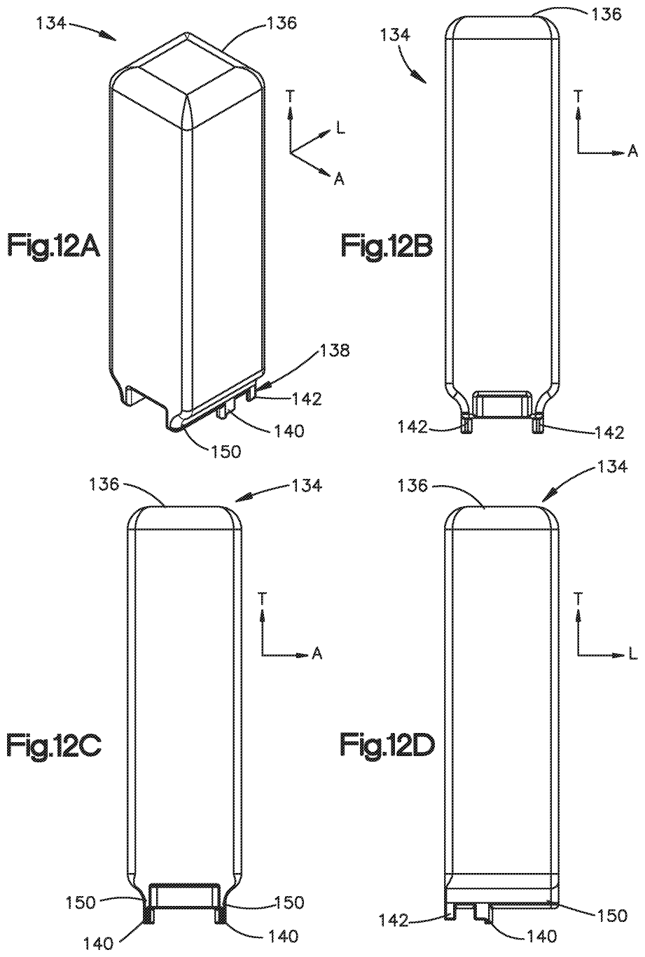

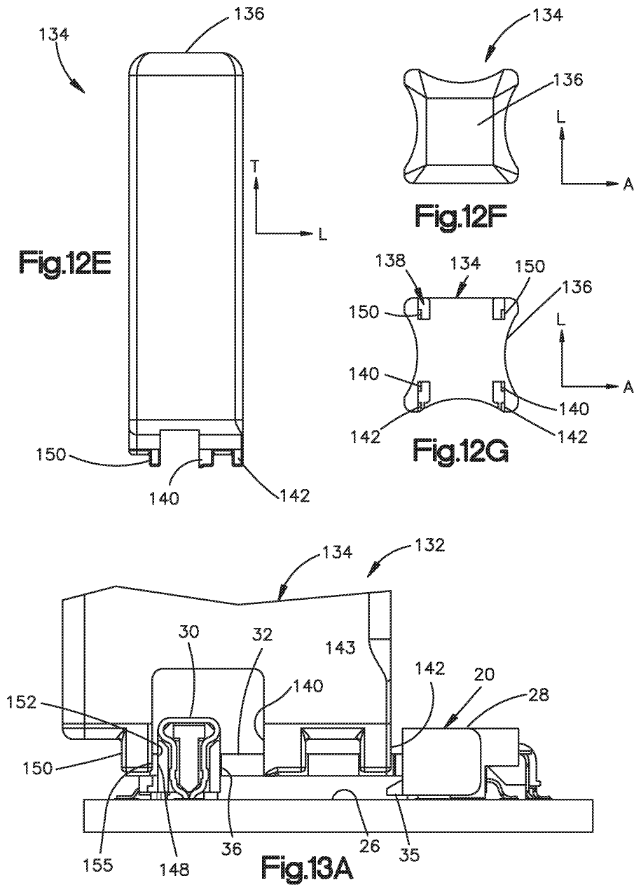

Referring now also to FIGS. 12A-12G, the actuator tool 134 can include an actuator body 136 and at least one projection 138 that extends from the actuator body 136 along the transverse direction T. For instance, the at least one projection 138 can extend down from the actuator body 136. The at least one projection 138 can be configured to urge the at least one latch finger 40 to the open position in the manner described above. Further, the at least one projection 138 can be configured to apply a rearward force to the interconnect module 24 that urges the interconnect substrate 32 to move in the rearward direction as described above. In one example, the rearward force can be applied to the interconnect substrate 32. Further still, the at least one projection 138 can be configured to apply the forward force that urges the interconnect substrate to move in the forward direction as described above.

The at least one projection 138 can include at least one latch engagement projection 140 that is configured to apply the force to the deflectable latch finger 40 that urges the at least one latch finger 40 to the open position against the biasing force of the latch arm 38. In one example, the at least one latch engagement projection 140 can include a plurality of latch engagement projections 140. For instance, the actuator tool 134 can include any number of latch engagement projections 140 as desired that are configured to urge the deflectable latch fingers 40 to the open position. Thus, during operation, the at least one latch engagement projection 140 can be aligned with the respective at least one latch finger 40 along the transverse direction. Movement of the at least one latch engagement projection 140 in the downward direction provides the force that urges the at least one deflectable latch finger 40 to the open position. The at least one projection 140 can move downward by moving the actuator body 136 downward. Alternatively, the at least one projection 140 can be telescopically movable downward. In one example, the at least one latch engagement projection 140 can include first and second latch engagement projections 140 that are opposite each other along the lateral direction. For instance, the first and second latch engagement projections 140 can be aligned with each other along the lateral direction A.

The at least one projection 138 can include at least one biasing projection 142 that is configured to apply a force that urges the interconnect substrate 32 to move in at least one of the forward direction and the rearward direction. For instance, the at least one biasing projection 142 can abut a corresponding at least one engagement surface 144 of the interconnect module 24. The at least one engagement surface 144 can be defined by the interconnect substrate 32. Alternatively, the at least one engagement surface 144 can be defined by any alternative structure of the interconnect module 24. The at least one engagement surface 144 can be configured as a rearward engagement surface 146 that is adjacent the at least one biasing projection 142 in the rearward direction. The at least one rearward engagement surface 146 can face at least partially forward so as to generally face the at least one biasing projection 142. When the at least one biasing projection 142 is aligned with the rearward engagement surface 146 along the longitudinal direction L, movement of the actuator tool 134 causes the at least one biasing projection 142 to apply the force to the interconnect module 24 in the rearward direction that urges the interconnect substrate 32 to move in the rearward direction as described above. For instance, the at least one biasing projection 142 can abut the rearward engagement surface 146. The at least one biasing projection 142 can be aligned with the rearward engagement surface 146 along the longitudinal direction L by moving the actuator tool 134 downward. Alternatively, the at least one biasing projection 142 can be telescopically movable downward as described above.

The at least one biasing projection 142 can further be configured to apply a force that urges the interconnect substrate 32 to move the forward direction. For instance, the at least one engagement surface 144 of the interconnect module 24 can include a forward engagement surface 148 is adjacent the at least one biasing projection 142 in the forward direction. The at least one forward engagement surface 148 can face at least partially rearward so as to generally face the at least one biasing projection 142. When the at least one biasing projection 142 is aligned with the forward engagement surface 148 along the longitudinal direction L, movement of the actuator tool 134 causes the at least one biasing projection 142 to apply the force to the interconnect module 24 in the forward direction that urges the interconnect substrate 32 to move in the forward direction as described above. For instance, the at least one biasing projection 142 can abut the forward engagement surface 148. The at least one biasing projection 142 can be aligned with the forward engagement surface 148 along the longitudinal direction L by moving the actuator tool 134 downward. Alternatively, the at least one biasing projection 142 can be telescopically movable downward. It should be appreciated that the at least one biasing projection 142 can include a plurality of biasing projections 142. For instance, the at least one biasing projection 142 can include first and second biasing projections 142 that can be spaced from each other along the lateral direction A. For instance, the first and second biasing projections 142 that can be aligned with each other along the lateral direction A.

It should be appreciated that the at least one biasing projection 142 can include at least one single biasing projection 142 that is configured to apply the forward and rearward forces, selectively, to both the forward engagement surface 148 and the rearward engagement surface 146. In this regard, the interconnect substrate 32 can include at least one aperture 143 (see FIGS. 13A-13B) that extends therethrough along the transverse direction T. The at least one aperture 143 can have an enclosed perimeter. Alternatively, the at least one aperture can be a pocket that is open to a respective one of the sides of the interconnect substrate that are opposite each other along the lateral direction A. Each at least one aperture 143 can be sized to receive a respective one of the biasing projections 142. Thus, the at least one aperture 143 can be at least partially defined by each of the rearward engagement surface 146 and the forward engagement surface 148.

Alternatively, the at least one biasing projection 142 can include a forward biasing projection and a separate rearward biasing projection. The forward biasing projection can be configured to apply the biasing force to the forward engagement surface 148, and the rearward biasing projection can be configured to apply the biasing force to the rearward engagement surface 146. The forward engagement surface 148 and the rearward engagement surface 146 can thus be defined by separate apertures or pockets that extends through the interconnect substrate 32 along the transverse direction T. Alternatively, the forward engagement surface 148 and the rearward engagement surface 146 can thus be defined by the same aperture or pocket that extends through the interconnect substrate 32 along the transverse direction T and is elongate so as to receive the forward and rearward biasing projection 142.

With continuing reference to FIGS. 12A-12G, the at least one projection 138 can include at least one stabilizing projection 150. The at least one stabilizing projection 150 can abut a stabilization surface 152 of the interconnect module 24 so as to provide an additional abutment with the interconnect module 24. The additional abutment can assist in maintaining the position of the actuator tool 134 with respect to the interconnect module. The stabilization surface 152 can be defined by the interconnect substrate 32. Alternatively, the stabilization surface 152 can be defined by any alternative surface of the interconnect module 24. The at least one stabilizing projection 150 can abut a rear edge 155 of the interconnect substrate 32 that extends in a plane defined by the lateral direction A and the transverse direction T. Thus, it should be appreciated in one example that the at least one stabilizing projection 150 can define the forward biasing projection. Thus, the at least one stabilizing projection 150 can be referred to as the at least one forward biasing projection as described above. The forward engagement surface can be defined by the rear edge 155. Thus, at least one biasing projection 142 can define the rearward biasing projection. Alternatively still, at least one stabilizing projection 150 and the at least one biasing projection 142 can each define the forward biasing projections. Alternatively still, the latch engagement projection 140 can further define both of the forward biasing projection and the rearward biasing projection.

In one example, the at least one stabilizing projection 150 can include a plurality of stabilizing projections 150. For instance, the at least one stabilizing projection 150 can include first and second stabilizing projections that are spaced from each other along the lateral direction A. In one example, the first and second stabilizing projections can be aligned with each other along the lateral direction A. Similarly, in one example, the at least one stabilization surface 152 can include a plurality of stabilization surfaces 152. For instance, the at least one stabilization surface 152 can include first and second stabilization surfaces 152 that are spaced from each other along the lateral direction A. In one example, the first and second stabilization surfaces 152 can be aligned with each other along the lateral direction A.

In one example, the at least one latch engagement projection 140 can be disposed between the at least one biasing projection 142 and the at least one stabilizing projection 150 along the longitudinal direction L. For instance, the at least one latch engagement projection 140 can be disposed closer to the at least one biasing projection 142 than to the at least one stabilizing projection 150 along the longitudinal direction. The at least one biasing projection 142 can be spaced from the at least one latch engagement projection 140 in the forward direction. Alternatively, the at least one biasing projection 142 can be spaced from the at least one latch engagement projection 140 in the rearward direction. In this regard, it should be appreciated that the projections 140, 142, and 150 can be arranged in any manner as desired. In this regard, the at least one projection 138 can define first and second third pairs of projections, wherein the projections of each pair of are aligned with each other along the lateral direction A. Further the pairs are spaced from each other along the longitudinal direction L. The forward pair can define the forward pair and the rearward biasing projections. The middle pair can define the latch engagement projections. The rear pair can define the forward biasing projections. It is recognized that the at least one latch engagement projection 140, the at least one biasing projection 142, and the at least one stabilizing projection can be arranged in any suitable alternative arrangement as desired.

In some examples, the latch 36 can be made from plastic or other suitable material. For instance, as described above, the latch 36 can be made from any suitable thermally conductive material as described herein. It is recognized that the latch 36 can present several advantages. For instance, the latch 36 can be sized relatively small, with little mass. Further, the latch 36 can be manufactured at low-cost, and can be formed from molded or injected plastic in some examples. As will be described in more detail below, however, the latch 36 can alternatively be metal. Further, the latch 36 can be fully captured between the interconnect substrate 32 and the host substrate 26. Thus, in some examples, the latch 36 is contained within the footprint of one or both of the host substrate 26 and the interconnect substrate 32 along a respective plane that is defined by the longitudinal direction L and the lateral direction A. The latch 36 can further be easy to prototype, or in some instances manufacture, using 3D printing technology.

While the latch 36 can be made from a thermally insulative material such as plastic, the latch 36 can alternatively, be made from metal or an alternative material having a high thermal conductivity. The latch 36 can further include one or more features or insert(s) that are configured to conduct heat from the interconnect substrate 32 to the host substrate 26. Such features are described in more detail below. Thus, in some examples, the latch 36 can allow a high thermal conductivity path between the interconnect substrate 32 and host substrate 26.

Further, the latch has been described as having at least one latch finger configured to engage one of the interconnect substrate 32 and the host substrate 26. The at least one latch finger can include at least one movable latch finger that is movable with respect to the latch base. The movable latch finger can be configured as the deflectable latch finger 40 that is supported by a corresponding at least one deflectable latch arm 38, as described above. It is recognized, however, that the movable latch finger can be alternatively constructed as desired. For instance, at least one of the movable fingers up to all of the movable latch fingers can be configured as a telescopic latch finger. The telescopic latch finger embedded in the latch body 52 in a retracted position, and can be telescopically movable along the transverse direction T to an extended position whereby the telescopic latch finger extends out from the latch body 52. Thus, the latch aperture 42 can be brought into alignment with the telescopic latch finger when the interconnect substrate 32 is mated with the host module 22 while the telescopic latch finger is in the retracted position. The telescopic latch finger can then be moved to the extended position whereby the telescopic latch finger extends into or through the latch aperture 42, thereby preventing the interconnect module from backing out as described above. The telescopic latch finger can be disposed in the latch base 55 as desired. In this regard, the latch body 52 can include the latch base and at least one latch finger supported by the latch base, and no latch arms 38 in some examples. Thus, it should be appreciated that one or more up to all of the deflectable latch fingers 40 described herein can alternatively be configured as respective telescopic latch fingers. Alternatively or additionally, the fixed latch fingers 56 described herein can alternatively be configured as telescopic latch fingers. The attachment peg 48 described above can similarly be configured as a telescopic latch peg that is movable from a retracted position to an extended position.

It should be appreciated that the interconnect substrate 32 may be used in an optical transceiver, optical receiver or optical transmitter, each having at least one optical engine that is mounted onto the interconnect substrate 32. Alternatively, the interconnect substrate may be used in an electrical transceiver, electrical receiver, electrical transmitter, optical or electrical cables, or a cable connector. More generally the interconnect substrate 32 may be referred to as a daughter substrate. Thus, the latch 36 can be used to secure the daughter substrate to first and second electrical connectors mounted on a host substrate, where the first and second electrical connectors are separated in a longitudinal direction L and the daughter substrate is inserted into the first electrical connector in the longitudinal direction. Advantageously the footprint of the latch does not extend past that of the daughter substrate in certain examples. This allows components to be placed on the host substrate 26 adjacent the first and second electrical connectors without interfering with the latch 36. Also, in some examples, the latch 36 does not extend above the daughter substrate along the transverse direction T, thereby allowing placement of other elements, such as an adjacent PCB, in this region. In other words, the latch 36 does not extend above the transceiver, receiver, or transmitter, in some examples.

As disclosed above, the latch 36 may contain features that facilitate heat transfer between the interconnect substrate 32 and host substrate 26. Generally, the latch 36 alone or in combination with or other thermally conductive elements can define a thermal bridge between the interconnect substrate 32 and host substrate 26. The thermal bridge can be operable to transfer or dissipate heat from the interconnect module 24, such as an optical transceiver, to the host substrate 26 that supports the first and second electrical connectors 28 and 30. It will be appreciated that the thermal bridge of the type described herein can create a thermally conductive path from and to any two surfaces. The two surfaces can be oriented parallel to each other. Such surfaces can be, but not limited to, a surface of a printed circuit board, a housing, a cold plate, a heatsink, a chip package having an integrated circuit, or the like.

The thermal bridge can be resiliently compressible so as to be in contact with both the interconnect substrate 32 and the host substrate 26 when the interconnect module 24 is mated to the host module 22 as described below. In particular, it is recognized that the second electrical connector 30 can be configured as a compression connector whose electrical contacts can compress along the transverse direction as the interconnect substrate 32 is brought down on to the second electrical connector 30. In this regard, the rear end of the interconnect substrate 32 can be brought down against the electrical contacts of the second electrical connector 30 along the transverse direction T as the front end of the interconnect substrate 32 is received in the receptacle of the first electrical connector 28 along the longitudinal direction L so as to mate the interconnect substrate 32 with the first electrical connector 28. As the rear end of the interconnect substrate is brought down against the electrical contacts of the second electrical connector 30, the electrical contacts compress, thereby applying an upward force to the rear end of the interconnect substrate 32. Once the interconnect substrate 32 is fully mated with the first electrical connector 28, the electrical contacts of the second electrical connector 30 can urge the rear end of the interconnect substrate 32 upward away from the host substrate 26. Thus, the thermal bridge can desirably be configured to contact both the host substrate 26 and the interconnect substrate 32 when the interconnect substrate 32 is fully mated with the first electrical connector 28. However, it should be appreciated that the thermal bridge can be resiliently compressible. Thus, the thermal bridge can resiliently compress along the transverse direction when the rear end of the interconnect substrate 32 is brought down against the electrical contacts of the second electrical connector 30 as the interconnect substrate 32 is being mated with the first electrical connector 28. When the rear end of the interconnect substrate 32 is subsequently urged upward away from the host substrate 26 when the interconnect substrate 32 is fully mated with the first electrical connector 28, the thermal bridge can remain in contact with the interconnect substrate 32 and maintain a contact force against the interconnect substrate 32. Similarly, when the front end of the interconnect substrate 32 is urged upward away from the host substrate by the electrical contacts of the front electrical connector as until reaches an equilibrium position in the receptacle of the front electrical connector 28, the thermal bridge can remain in contact with the interconnect substrate 32 and maintain a contact force against the interconnect substrate 32.

Referring to FIG. 14, when the interconnect substrate 32 is mated with the host module 22, a gap 58 can be defined between the top surface of the host substrate 26 and the interconnect substrate 32 at a location between the first and second electrical connectors 28 and 30. The interconnect system 20 can further include a thermal bridge 60 that is disposed in the gap 58. At least a portion of the gap 58 and at least a portion of the gap 34 described above can coincide with each other. Thus, the thermal bridge 60 can also be disposed in the gap 34. Similarly, the latch 34 can be disposed in the gap 58. The gap 58 can have a height along the transverse direction T that is in the range of substantially 1.1 mm to substantially 1.5 mm; however, larger and smaller gaps 58 are possible. Over the life of the system the gap 58 may vary by ±0.2 mm, depending on the temperature, orientation, and possible mechanical loads on the host substrate 26 and interconnect module 24. Some variation in the gap 58 is also expected from part-to-part variation in the gap height based on manufacturing tolerances. The thermal bridge 60 can advantageously provide a low impedance thermally conductive path from the interconnect substrate 32 to the host substrate 26 when the interconnect substrate 32 is mated with the host module 22, and can maintain a low thermal impedance path between the interconnect substrate 32 and the host substrate 26 while accommodating the differences and variations in the height of the gap 58. This can be particularly advantageous when the interconnect module 24 defines an optical transceiver, optical transmitter, or optical receiver.

The thermal bridge may be combined with or integrated with any of the latches described herein. Thus, it can be said that the interconnect system 20 can include the thermal bridge 60. In some examples, it can be said that the latch 36 can include the thermal bridge 60. The thermal bridge 60 may be installed prior to the installation of the latch 36 or may be installed as part of the installation of the latch 36. The host substrate 26 may have thru hole conductive vias or thermal dissipation layers in the region of the host substrate 26 adjacent the thermal bridge to facilitate transfer of heat from the thermal bridge 60 away from the interconnect module 24.

It is therefore desirable to provide robust mechanical contact between the thermal bridge 60 and the bottom surface of the interconnect substrate 32 to provide a reliable conductive heat transfer path. Similarly, it is desirable to provide robust mechanical contact between the thermal bridge 60 and the top surface of the host substrate 26 to provide a reliable conductive heat transfer path. As will be appreciated from the description below, the thermal bridge 60 can be slidable relative to at least one of the bottom surface of the interconnect substrate 32 and the top surface of the host substrate 26 during installation of the thermal bridge 60. The thermal bridge 60 described herein can be both slidable relative to at least one of the bottom surface of the interconnect substrate 32 and the top surface of the host substrate 26, while also providing for robust thermal contact with each of the host substrate 26 and the interconnect substrate 32. In one example, the thermal bridge 60 can be compliant along the transverse direction T. Various systems and methods for achieving thermal bridge compliance are described below. Further, it is appreciated that the compression force that the thermal bridge 60 applies against the host substrate 26 and the interconnect substrate 32 can be controlled. For instance, the force can be sufficiently high to provide reliable thermal contact between the thermal bridge 60 and each of the interconnect substrate 32 and the host substrate 26. On the other hand, the force can be sufficiently low so as to not mechanically strain the structural integrity of the electrical connectors 28 and 30, the connector solder joints to the host substrate 26 or the electrical contacts with the interconnect substrate 32. Further, the thermal bridge 60 can conform to small misalignments in the parallelism or flatness of the top surface of the host substrate 26 and the bottom surface of the interconnect substrate 32.

Referring now to FIG. 15, the thermal bridge 60 can include a thermally conductive member. The thermally conductive member can be configured as a spring member 59 in some examples. The spring member 59 can be compressible along the transverse direction T. As will be appreciated from the description below, the spring member 59 can be elastically deformable. It should also be appreciated, however, that a portion of the spring member 59 can be plastically (i.e., inelastically) deformable as desired. In one example, the spring member 59 can be defined by an elastic thermal pad 62. The thermal pad 62 may be used alone. Alternatively, the thermal pad 62 can be enclosed in an inverted thermally conductive cup 64. The cup 64 can be made of metal in certain examples. The thermally conductive cup 64 can be movable up and down along the transverse direction T, and can be captured in a horizontal direction. That is, the cup 64 can be constrained with respect to movement in a plane defined by the longitudinal direction L and the lateral direction A. For instance, the cup 64 can be prevented from moving in the plane. In one example, the cup 64 can include a cup body 65 and at least one projection 66, such as a plurality of projections 66 that extend from the cup body 65. The projections 66 can extend from the cup body 65 along the transverse direction T. The projections 66 can be configured to be inserted into respective mounting apertures 68 in the host substrate 26. In one example, the mounting apertures 68 can be configured as slots, and the thermal bridge to be slid into position after the interconnect substrate 32 has been mated with the first and second electrical connectors 28 and 30. In particular, the projections 66 can slide along the slot as the thermal bridge 60 is installed. Alternatively, the apertures 68 can be configured as through-holes, and the thermal bridge may be positioned on the host substrate 26, such that the projections 66 extend through the through-holes, prior to mating the interconnect substrate 32 with the first and second electrical connectors 28 and 30.

While the thermal bridge 60 can be mounted to the host substrate 26 in one example, the thermal bridge 60 can alternatively be mounted to the interconnect substrate 32 if desired. Thus, while the mounting apertures 68 extend into or through the host substrate 26 in one example, the mounting apertures 68 can alternatively extend into or through the interconnect substrate 32. Alternatively still, the mounting apertures 68 can extend into or through both the host substrate 26 and the interconnect substrate 32. First ones of the projections 66 can thus extend upward, while second ones of the projections 66 extend down. Thus, the latch engagement projections 66 can extend into the mounting apertures of the interconnect substrate 32, and the biasing projections 66 can extend into the mounting apertures of the host substrate 26. Thus, it can be said that the thermal bridge 60 can be mounted to at least one substrate that can be defined by one or both of the host substrate 26 and the interconnect substrate 32. For instance, the cup 64 can include projections 66 that extend into mounting apertures of at least one of the host substrate 26 and the interconnect substrate 32, so as to position the thermal bridge 60 between the interconnect substrate 32 and the host substrate 26.

As described above, the thermal pad 62 can be compressible along the transverse direction T. Thus, when the thermal bridge 60 is positioned between the interconnect substrate 32 and host substrate 26, the thermal pad 62 can compress along the transverse direction T. In particular, the cup body 65 can apply a compressive force F against the thermal pad 62 when the cup body 65 is mounted to the at least one of the interconnect substrate 32 and the host substrate 26. The top surface of the cup 64 can be in robust mechanical contact with the bottom surface of the interconnect substrate 32. Simultaneously, the bottom surface of the thermal pad can be in robust mechanical contact with the top surface of the host substrate 26. Further, the top surface of the thermal pad can be in robust mechanical contact with the cup body 65. Alternatively, the cup 64 can be configured such that a bottom surface of the cup 64 is in robust mechanical contact with the top surface of the host substrate 26, and the top surface of the thermal pad can be in robust mechanical contact with the bottom surface of the interconnect substrate 32.

The cup 64 can have a height that is selected such that the cup 64 does not bottom out against the substrate to which the cup 64 is mounted over the full range of expected mechanical tolerance in the height of the gap 58. Further, the elastic thermal pad 62 can have a volume that is selected to define a horizontal gap between the thermal pad 62 and the cup body 65. Thus, the thermal pad 62 can be expandable along the horizontal direction as the pad 62 is compressed along the transverse direction T due to Poisson's effect. Poisson's effect is depicted in the figure by the horizontally extending arrows from the elastic thermal pad 62. An advantage of enclosing the thermal pad in the cup 64 is to avoid subjecting the thermal pad 62 to shear forces that might otherwise damage the pad 62 if the thermal bridge 60 slides against the substrate to which the thermal bridge 60 is mounted during installation of the thermal bridge 60. Metal may be selected as the material of the cup 64, since it is easily formed and has high thermal conductivity. It should be appreciated, however, that any suitable thermally conductive material can be used.

Referring now to FIG. 16, in another example, the spring member 59 of the thermal bridge 60 can be configured as a thermally conductive member 70 such as a spring clip 70. The spring clip 70 can be deformable both plastically and elastically. The spring clip 70 can be disposed in the gap 58 between the interconnect substrate 32 and host substrate 26. The spring clip 70 can define an upper end 70a and a lower end 70b. The upper end 70a can define a top surface of the spring clip 70 that is configured to abut the bottom surface of the interconnect substrate 32. The lower end 70b can define a bottom surface of the spring clip 70 that is configured to abut the top surface of the host substrate 26. The spring clip 70 can include an upper stiffener 72 that is disposed between the upper end 70a and the lower end 70b, and bears against the upper end 70a. The spring clip 70 can further include a lower stiffener 74 that bears against the lower end 70b. The upper and lower stiffeners 72 and 74 can be defined by separate structures or a single monolithic structure while maintaining the compliance of the thermal bridge 60 as described herein. Thus, the upper and lower stiffeners of the single monolithic structure can be resiliently movable with respect to each other along the transverse direction T. The upper stiffener 72 can define a top surface that is substantially planar, and thus can assist in maintaining the substantial planarity of the top surface of the spring clip 70. Similarly, the lower stiffener 74 can define a bottom surface that is substantially planar, and thus can assist in maintaining the substantial planarity of the bottom surface of the spring clip 70. In some examples, at least one or both of the upper and lower ends 70a and 70b, respectively, can include a securement member that is configured to engage a complementary securement member of a respective at least one or both of the upper and lower stiffeners 72 and 74 so as to secure the spring clip 70 to the respective at least one or both of the upper and lower stiffeners 72 and 74. It should be appreciated of course, that the spring clip 70 can be devoid of one or both of the upper and lower stiffeners 72 and 74, respectively, as desired.

The substantial planarity of the upper and bottom surfaces of the spring clip 70 may allow for reliable mechanical contact between the spring clip 70 and both the interconnect substrate 32 and host substrate 26, thereby facilitating heat transfer from the interconnect substrate 32 to the host substrate 26. In particular, a direct heat conduction path exists in the spring clip 70 from the interconnect substrate 32 to the host substrate 26. The spring clip 70 can be fabricated from any suitable thermally conductive material as desired. For instance, the spring clip 70 can be fabricated from any suitable metal. In one example, the spring clip 70 is formed from a high thermal conductivity metal, such as aluminum, copper, beryllium copper, or an engineered material like, graphite-copper or graphite aluminum.

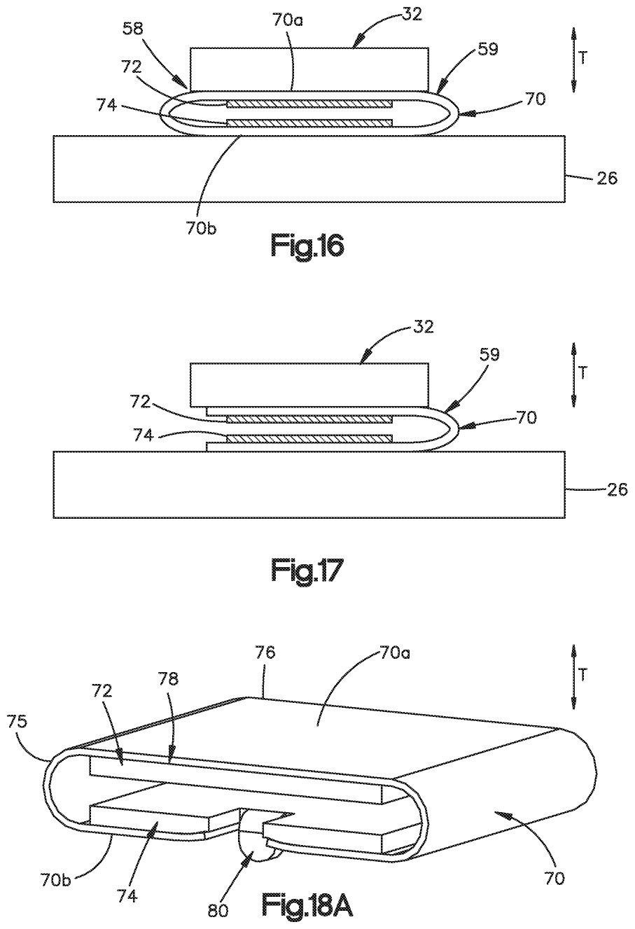

The spring clip 70 may take the form of any suitable shape as desired. The spring clip 70 can define an outer perimeter in a plane that is defined by the transverse direction T and the lateral direction A. In one example, the outer perimeter can be racetrack shaped, as illustrated in FIG. 16. Otherwise described, the outer perimeter can define an elongated “0” shape or an elongated oval shape, whereby the upper and lower ends are substantially planar as described above. Alternatively, the outer perimeter of the spring clip 70 may define an elongated “C” shape as illustrated in FIG. 17A. The upper and lower ends of the “C” can be substantially planar in the manner described above. In both FIGS. 15A and 17A the spring clip is shown extending past the sides of the interconnect substrate 32 along the lateral direction A. It should be appreciated that in other examples the spring clip 70 does not extend past the opposed lateral sides of the interconnect substrate 32. Further, the spring clip 70 can be constructed so as to not extend past the opposed lateral sides of the host substrate 26.

In one example, as illustrated in FIG. 18A, the spring clip 70 can include an outer sheath 76 and at least one inner stiffener 78. The outer sheath 76 can be made from graphite copper in one example. The outer sheath 76 can define the upper and lower ends 70a and 70b, respectively, of the spring clip 70 as described above. Thus, the external surface of the spring clip 70, which defines the upper and bottom surfaces of the spring clip 70, can be defined by an elastically deformable band 75. For instance, the band, 75 can be thermally conductive. In one example, the band 75 can be made from a graphite copper material. The at least one stiffener 78 can be formed from any suitable thermally conductive material. In one example, the at least one stiffener 78 can be made from copper. Alternatively, the at least one stiffener 78 can be made from copper tungsten or beryllium copper. The at least one stiffener 78 can include the upper stiffener 72 and the lower stiffener 74 as described above. One of the upper and lower stiffeners 72 and 74 can include an attachment member that is configured to attach to the host substrate 26. The attachment member can be configured as an attachment peg 80 that extends in a vertical direction and can engage with the mounting aperture 68 in the substrate to which the spring clip 70 is mounted, thereby registering the spring clip in the horizontal direction. In one example, the mounting aperture 68 can extend into or through the host substrate 26. Thus, the attachment peg 80 can extend down from the lower stiffener 74 so as to be received by the mounting aperture 68 of the host substrate 26. In another example, the mounting aperture 68 can extend into or through the interconnect substrate 32. Thus, the attachment peg 80 can extend up from the upper stiffener 72 so as to be received by the mounting aperture 68 of the interconnect substrate 32. The attachment peg 80 may be formed by a stamping operation on the respective one of the lower stiffener 74 and upper stiffener 72. The lower stiffener 74 can also include a shallow recess on its bottom surface to prevent the end of the thermally conductive band 75 from protruding below the bottom plane of the thermal bridge 60 and impede the planarity and proper contact between the bottom surface of the thermal bridge 60 and the top surface of the host substrate 26.

As illustrated in FIG. 18B the spring clip 70 can be compressed from an uncompressed state along the transverse direction T. When the spring clip 70 is in its compressed state, the upper and lower stiffeners 72 and 74 can contact each other. Alternatively, the upper and lower stiffeners 72 and 74 can remain spaced from each other when the spring clip 70 is in its compressed state. Some possible representative thickness for the various elements of the thermal bridge are illustrated in FIG. 18B. For instance, the thermally conductive band 74 can have any suitable thickness as desired. The thickness can be measured along the transverse direction T. In one example, the thickness can be in a range from approximately 1.0 mm and approximately 1.5 mm. For instance, the thickness of the sheath can be approximately 0.1 to 0.25 mm. Further, when the spring clip 70 is in its uncompressed state, the spring clip 70 can have any suitable uncompressed height from the top surface to the bottom surface along the transverse direction T. The uncompressed height can be at least equal to the height of the gap 58 along the transverse direction T. That is, the uncompressed height can be at least equal to the distance from the host substrate 26 to the interconnect substrate 32 along the transverse direction T. For instance, the uncompressed height can be greater than the height of the gap 58 along the transverse direction T. That is, the uncompressed height can be greater than the distance from the host substrate 26 to the interconnect substrate 32 along the transverse direction T. In one example, the uncompressed height can be in a range from approximately 1.5 mm to approximately 2.5 mm along the transverse direction T. For instance, the uncompressed height can be approximately 1.5 mm along the transverse direction T. Of course, it should be appreciated that the uncompressed height can be any suitable uncompressed height as desired. When the spring clip 70 is compressed between the interconnect substrate 32 and the host substrate 26, spring clip 70 can define any suitable compressed height that is less than the uncompressed height. The compressed height can be defined by the distance from the top surface of the host substrate 26 to the bottom surface of the interconnect substrate 32 along the transverse direction T. The compressed height can be in a range from approximately the 1.1 to approximately 1.5 mm along the transverse direction T. For the COBO module, the compressed height can be the range from approximately 2.1 mm to approximately 2.3 mm. It should be appreciated that the spring clip 70 can be compressible to a fully compressed height that is less than the compressed height which can be defined when the spring clip 70 contacts each of the host substrate 26 and the interconnect substrate. For instance, the fully compressed height can be defined when the upper and lower stiffeners 72 and 74 contact each other. In one example, the fully compressed height can be in the range from approximately 0.75 mm to approximately 1.0 mm. The upper and lower stiffeners 72 and 74 can have a high emissivity in the infrared to facilitate infrared radiative heat transfer, since these elements may not be in mechanical contact, even when the spring clip 70 is in the compressed state. Without being bound by theory, it is believed that the thermal conduction from the interconnect substrate 32 to the host substrate 26 occurs primarily along the outer sheath 76. As described above, the outer sheath 76 can also provide the spring force that urges the upper and lower ends 70a and 70b, respectively, against the interconnect substrate 32 and the host substrate 26, respectively. Alternatively, the interconnect system 20 can include a separate biasing member that provides the spring force that urges the upper and lower ends 70a and 70b, respectively, against the interconnect substrate 32 and the host substrate 26, respectively.

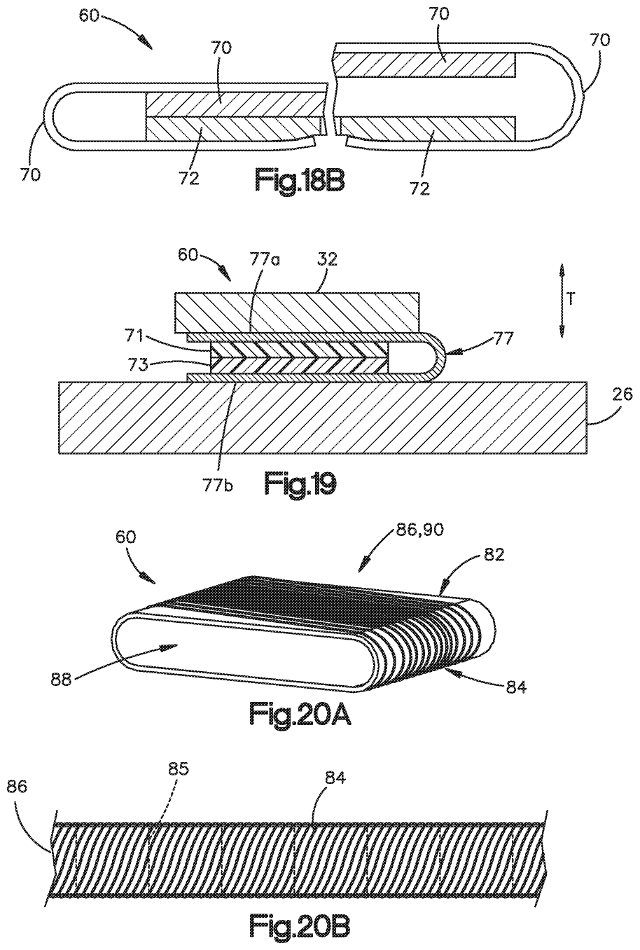

Referring now to FIG. 19, another thermal bridge 60 can include first and second (or upper and lower, respectively) thermally conductive elements 71 and 73 that can define thermally conductive bodies such as thermal gap pads that are configured to contact each other along the transverse direction T, and have an elasticity that applies a contact force to an outer thermally conductive member 77 that is configured to urge the outer thermally conductive member 77 against the host substrate and interconnect substrate. The thermally conductive member 77 can define an upper wall 77a that extends along the first thermally conductive element 71, and a lower wall 77b that extends along the second thermally conductive element 73. The upper and lower walls 77a and 77b can be monolithic with each other. For instance, the thermally conductive member 77 can be a substantially c-shaped member that defines the upper and lower walls 77a and 77b. The bridge 60 can be placed onto the upper surface of the host substrate 26, such that the thermally conductive bodies 71 and 73 can be forced and compressed against each other along the transverse direction T by the interconnect substrate 32 (via the thermally conductive member 77) when the interconnect substrate 32 is mated with the host module. For instance, the interconnect substrate 32 and the host substrate 26 can combine to urge the upper and lower walls 77a and 77b against the first and second thermally conductive bodies 71 and 73, respectively. The elasticity of the thermally conductive bodies 72 and 74 when compressed can apply the force against the thermally conductive member 77 that urges the walls 77a and 77b to contact the interconnect substrate and the host substrate. The upper wall 77a defines a surface along which the interconnect substrate 32 can slide as the interconnect substrate 32 is mated with the host module. Alternatively the thermal bridge can include a single thermally conductive element or a plurality of thermally conductive elements. In other examples, the first and second thermally conductive bodies 71 and 73 can define one single monolithic body.

Referring now to FIGS. 20A-20B, in another example the thermal bridge 60 can include a forming element 82 and at least one wire 84 that surrounds the forming element 82. Thus, the thermally conductive member can be configured as the at least one wire 84. The wire 84 can contact both the bottom surface of the interconnect substrate 32 and the top surface of the host substrate 26. Thus, the at least one wire 84 can define a thermally conducive path from the interconnect substrate 32 to the host substrate 26. The at least one wire 84 can be helically wrapped around the forming element 82. Alternatively, the wire 84 can define a plurality of enclosed rings that are disposed adjacent each other about the forming element 82. In one example, the forming element 82 may define a mandrel that is removed after the at least one wire 84 is wrapped around it. Alternatively, the forming element 82 can remain in place so as to form part of the thermal bridge 60. In one example, the forming element 82 can be defined by a compliant material. The compliant material can be defined by a compliant foam or the like. Alternatively or additionally, the forming element 82 can be defined by a band 86 that defines a void 88 that extends therethrough along the longitudinal direction L. The band 86 can be defined by a hollow compliant core 90. In one example, the void 88 can extend through the band 86 along the longitudinal direction L. Adhesive may be applied to the outer surface of the forming element 82 so as to attach the at least one wire 84 to the outer surface of the forming element 82 while maintaining the alignment of the at least one wire 84 on the outer surface. The at least one wire 84 may have a round cross-section or may have one or more flattened sides as desired.

The at least one wire 84 can have any suitable cross-sectional dimension as desired. For instance, the at least one wire 84 can have a square shape or a rectangular or otherwise elongate cross-section having a cross-sectional dimensions in the range of approximately 0.25 mm by approximately 1 mm, as one example. In another examples, the dimension of elongation can be greater than the stated approximately 1 mm, . . . . When the wire 84 has a circular cross-section, the cross-sectional dimension can define a diameter. In one example, the cross-sectional dimension can range from approximately 2 mils to approximately 10 mils. For instance, the cross-sectional dimension of the at least one wire 84 can range from approximately 0.05 mm and approximately 0.25 mm.

The at least one wire 84 can be made from any suitable thermally conductive material as desired. For instance, the at least one wire 84 can be made from gold-plated copper to provide a conductive thermal path from the interconnect substrate 32 to the host substrate 26. It has been found that gold-plated copper has high thermal conductivity and resists surface oxidation that impeded heat transfer. The forming element 82 can have any suitable height along the transverse direction T. For instance, in one example, the height can range from approximately 1.5 mm to approximately 2 mm. It should be appreciated that the heat transfer capability of the thermal bridge 60 can be increased when the length of the wire or outer sheath is reduced.

The forming element 82 can have a width along the lateral direction A that is less than the width of the interconnect substrate 32 along the lateral direction A. For example, the forming element 82 can have a width along the lateral direction A of approximately 7 mm or less. The forming element 82 can have a height along the transverse direction T that is greater than the gap 58 from the bottom of the interconnect substrate 32 and top of the host substrate 26 (see FIG. 14). For example, the forming element 82 can have a height that ranges from approximately 1.5 mm to approximately 2 mm. The forming element 82 can also be formed from a length along the longitudinal direction L that is many times greater than the distance from the first electrical connector 28 to the second electrical connector 30 along the longitudinal direction L (see FIG. 14). Thus, a long length of wire 84 may be wrapped around the mandrel. Individual lengths, suitable for positioning between the interconnect substrate 32 and host substrate 26 with respect to the transverse direction T, and between the first electrical connector 28 and the second electrical connector 30 with respect to the longitudinal direction can be cut from the long length of wound wire along cut lines 85. Thus, the resulting cut wound wire 84, and cut forming element 82 if the forming element 82 is to remain as part of the thermal bridge 60, can be sized so as to not extend past the footprint of the interconnect substrate 32. The thermal bridge 60 can be configured to be disposed at least partially in the through hole 54 of the latch 36 (see FIG. 9). Alternatively, the thermally conductive member can be wrapped about the latch 36. Thus, in some examples, the latch 36 can define the forming element 82.

Thus, the at least one wire 84 can conduct heat along the successive lengths of wire coil 92 that span the gap 58 between the bottom surface of the interconnect substrate 32 and the top surface of the host substrate 26. The wire coil 92 can further be compliant along the transverse direction T in the manner described above. In one example, the deformation of the wire coil 92 in the transverse direction T can be purely elastic, which can ensure that the contact forces are maintained within an acceptable range while the distance between the host substrate 26 and the interconnect substrate 32 varies. In other examples, the deformation of the wire coil 92 can be a combination of plastic deformation and elastic deformation, with the elastic deformation ensuring the contact forces are maintained within an acceptable range and the plastic deformation limiting the maximum contact force being applied to the host substrate 26 and interconnect substrate 32. The maximum force (as well as the minimum force) can be adjusted by varying the cross section, the moment of inertia, the length, spacing and material of the wire(s) and/or the configuration of the forming element 82. These same force considerations may be used in the other examples of the thermal bridge 60 described herein. That is, it can be desirable for all thermal bridges disclosed herein to be elastically compressible along the transverse direction T so as to maintain the contact force against both the host substrate and the interconnect substrate as the interconnect substrate moves vertically away from the host substrate during and after mating with the host module as described herein. When the forming element 82 is not removed after the at least one wire 84 has been wound about the forming element 82, at least a portion of the conductive thermal path can extend through the forming element 82.

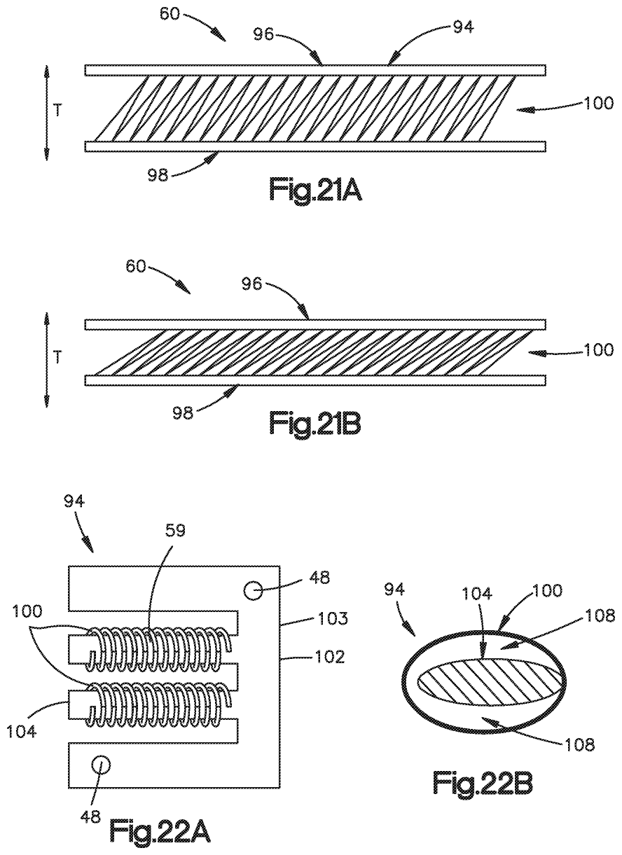

Referring now to FIGS. 21A-21B, in another example, the thermal bridge 60 can include a coil spring assembly 94. In some examples, the coil spring assembly 94 can be also referred to as a canted coil spring assembly as will become appreciated from the description below. Further, the thermal bridge 60 can include the canted coil spring assembly 94 in accordance with a number of examples. In the example illustrated in FIG. 21A, the coil spring assembly 94 can include an upper plate 96, a lower plate 98 opposite the upper plate 96 along the transverse direction T, and a coil spring disposed between the upper plate 96 and the lower plate 98. Thus, the spring member 59 of the thermal bridge 60 can be configured as a coil spring. In one example, the coil can be canted. Thus, the coil spring can be configured as a canted coil spring 100. The canted coil spring 100 can be inclined with respect to the transverse direction T. For instance, as illustrated in FIGS. 21A-22A, the windings of the canted coil spring 100 can lean horizontally as they extend in the upward direction from the host substrate 26 to the interconnect substrate 32. Alternatively, if desired, the coil spring can be configured as a standard coil spring oriented along the transverse direction T without being canted. Thus, unless otherwise indicated, the description herein with respect to the canted coil spring 100 can be applicable to a standard coil spring. As illustrated in FIG. 21A, the canted coil spring assembly 94 can be in a decompressed state when it is not disposed between the interconnect substrate 32 and host substrate 26. As illustrated in FIG. 21B, the canted coil spring assembly 94 can be in a compressed state with respect to the transverse direction T when it is disposed between the interconnect substrate 32 and host substrate 26. When the canted coil spring assembly 94 is in the decompressed state, the coils of the canted coil spring 100 can be oriented more vertically than when the canted coil spring assembly 94 is in the compressed state.

In operation, the top surface of the upper plate 96 can make mechanical contact with the bottom surface of the interconnect substrate 32. The bottom surface of the lower plate 98 can make mechanical contact with the top surface of the host substrate 26. A low impedance thermally conductive path across the thermal bridge 60 can be defined by the coils of the canted coil spring 100 and the upper and lower plates 96 and 98. That is, the thermal path from the interconnect substrate 32 to the host substrate 26 can have a lower impedance than the impedance from the interconnect substrate 32 to the host substrate 26 without the coil spring 100. One or more up to all of the upper plate 96, the lower plate 98, and the canted coil spring 100 can be fabricated from any suitable material, such as a metal, having a high thermal conductivity. In some examples, one or both of the upper plate 96 and the lower plate 98 may be eliminated. Thus, the windings of the canted coil 100 can make direct mechanical contact with one or both of the bottom surface of the interconnect substrate 32 and the top surface of the host substrate 26.

Referring now to FIG. 22A, the canted coil spring assembly 94 can include a thermal support housing 102, and at least one canted coil spring 100 that is mounted to the thermal support housing 102. For instance, the canted coil spring assembly 94 can include a plurality of canted coil springs 100 that are mounted to the thermal support housing 102. The thermal support housing 102 can be thermally insulative in one example, such as a plastic. Alternatively, the thermal support housing 102 can be thermally conductive, such as a metal. The thermal support housing 102 may have at least one thermal support arm 104. For instance, the thermal support housing 102 can include a plurality of arms 104. In one example, the thermal support housing 102 includes a thermal support body 103, and the at least one arm 104 that extends out from the thermal support body 103. The at least one arm 104 can be cantilevered from the thermal support body 103. For instance, the at least one arm 104 can be cantilevered from the thermal support body 103 along the lateral direction A. In one example, the thermal support housing 102 can include a plurality of arms 104 that are spaced from each other along the longitudinal direction L. Alternatively or additionally a pair of arms 104 can be spaced from each other along the lateral direction, for instance when the thermal bridge is configured to be placed between the interconnect substrate and the host substrate after the interconnect substrate has been mated with the host module. While the thermal support housing 102 is illustrated as including two arms 104 in FIG. 22A, it is contemplated that the thermal support housing 102 can include any suitable number of arms 104 as desired.

The canted coil spring assembly 94 can include a substantially linearly oriented canted coil spring 100 that is disposed about each of the arms 104. That is, the windings of the canted coil spring 100 can be spaced from each other along a substantially linear path. The thermal support housing 102 can further include at least one attachment member that is configured to attach to one or both of the host substrate 26 and the interconnect substrate 32. For instance, the thermal support housing 102 can include at least one attachment peg 48 such as a plurality of attachment pegs 48 that extend out from one or both of the top surface and the bottom surface of the thermal support housing 102 along the transverse direction T. The attachment pegs 48 can be configured to be inserted in a corresponding at least one aperture of one or both of the host substrate 26 and the interconnect substrate 32 so as to register the thermal support housing 102 with respect to the one or both of the host substrate 26 and the interconnect substrate 32 along one or both of the longitudinal direction L and the lateral direction A. Thus, the canted coil assembly 94 can be configured to attach to the host substrate 26 prior to mating the interconnect substrate 32 with the host module 22. Alternatively or additionally, the canted coil spring assembly 95 can include one or more deflectable fingers, one or more fixed fingers, or a combination of at least one deflectable finger and at least one fixed finger as described above. Thus, the canted coil assembly 94 can include the latch 36 as described herein.

The arms 104, and their supported canted coil springs 100, may be oriented in a direction that is angularly offset with respect to the insertion direction along which the interconnect substrate 32 is mated with the first and second electrical connectors 28 and 38. For instance, the at least one arm 104 can be elongate along a direction that is substantially perpendicular to the insertion direction. Otherwise stated, the at least one arm 104 can be elongate along the lateral direction A. Thus, the canted coil springs 100 can define a plurality of contact regions with the upper and lower plates 96 and 98 or the host and interconnect substrates 26 and 32, respectively, at the adjacent windings of the canted coil spring 100. The contact regions can be spaced from each other along a direction that is substantially perpendicular to the mating direction of the interconnect substrate 32. That is, the contact regions can be spaced from each other substantially along the lateral direction A. This reduces the chance of the canted coil springs 100 hanging up or wedging as the interconnect substrate 32 is mated with or unmated from the host module 22.

Referring now to FIG. 22B, the arms 104 can be oblong in cross section in a plane that is defined by the transverse direction T and the longitudinal direction L. For instance, the arms 104 have a width in the horizontal direction and a height along the transverse direction T that is less than the width. In one example, the width can be measured along the longitudinal direction L when the canted coil spring assembly 94 is installed between the interconnect substrate 32 and the host substrate 26. Accordingly, a gap 108 can be defined along the transverse direction T between the canted coil spring 100 and one or both of the top and bottom surfaces of the arms 104. The gap 108 provides clearance for compression of the canted coil spring 100 along the transverse direction T and tilting of the canted coil spring 100 as the thermal bridge 60 is compressed between the host substrate 26 and interconnect substrate 32. Further, the compressibility and tiltability of the canted coil spring 100 can maintain the canted coil spring 100 in an orientation such that the direction of compression is substantially normal to the top surface of the host substrate 26 and the bottom surface of the interconnect substrate 32. When the interconnect substrate 32 mates with or unmates from the host module 22, the canted coil spring 100 can be forced against one side of the respective arm 104 at a contact point. The canted coil spring 100 can then pivot about this contact point and tilt so as to reduce its height in the transverse direction T and fit between the top surface of the host substrate 26 and the bottom surface of the interconnect substrate 32. In other words the cross section of the arm 104 can maintain the principal compressible axis of the canted coil along the transverse direction by preventing the canted coil from rotating while preventing lateral motion relative to the latch finger, and while permitting a desired amount of compressibility.

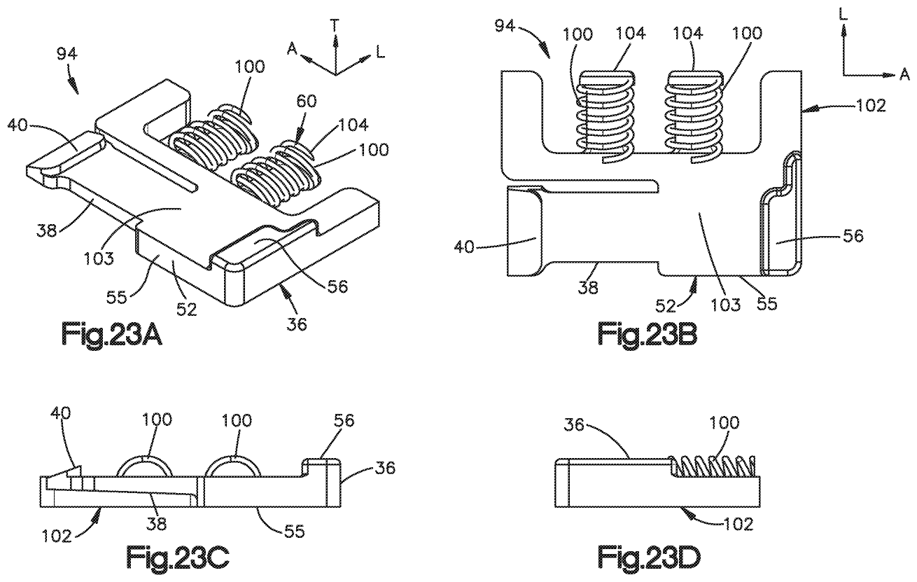

Referring now to FIGS. 23A-23D, the thermal support housing 102 of the canted coil spring assembly 94 of the type described above with respect to FIG. 22A-22B can also define the latch 36 of the type described above. Thus, it can be said that the thermal bridge 60 can include the latch 36. Alternatively, it can be said that the latch 36 can include a thermal bridge 60. The latch 36 can be monolithic with the thermal support housing 102. Further, the canted coil spring assembly 94 can be configured to be inserted between the host substrate 26 and the interconnect substrate 32 after the interconnect substrate 32 has been mated to the host module 22. The thermal support housing 102 can be include a latch body 52 that can include a latch base 55 and a latch arm 38 that extends out from the latch base 55 in the manner described above. In one example, the latch arm 38 can project out from the latch base 55 along the lateral direction A. Thus, the latch arm 38 can be configured as a side insertion latch of the type described above. Thus, the coil spring can be supported by the thermal support body 103, which can be monolithic with the latch body 52.

For instance, the latch 36 can include the deflectable latch finger 40 and the fixed latch finger 56 in one example. Thus, the deflectable latch finger 40 can be opposite the fixed latch finger 56 along the lateral direction A. It should be appreciated, of course, that the latch 36 of the thermal support housing 102 can include any one or more up to all of at least one latch arm 38, at least one deflectable latch finger 40, alone or in combination with at least one fixed latch finger 56 as desired. Thus, the latch 36 illustrated in FIGS. 23A-23D can be configured as any of the latches described above. The canted coil assembly 94 can be inserted between the interconnect substrate 32 and the host substrate 26 in the direction that the latch arm 38 is cantilevered until the deflectable finger 40 is aligned with a respective latch aperture 42 of the interconnect substrate 32 along the transverse direction T. The deflectable finger 40 is then inserted into the latch aperture 42, thereby securing the interconnect substrate 32 to the host module 22. The canted coil can define a sliding direction that is normal to its axis such that the coil maintains its canted position as it is slid. Sliding the canted coil along a direction perpendicular to its axis could cause the canted coil to be urged into a more upright, and less canted, orientation and impede the motion of the transceiver substrate by wedging itself between the transceiver substrate and the host board

The canted coil assembly 94 can further include at least one thermal support arm 104, and a canted coil spring 100 supported by the at least one thermal support arm 104 described above. The at least one thermal support arm can be elongate along the longitudinal direction L. Thus, adjacent windings of the canted coil spring 100 can be spaced from each other along the longitudinal direction L. When the latch 36 has secured the interconnect substrate 32 to the host substrate 26, the at least one canted coil spring 100 can bear against each of the top surface of the host substrate 26 and the bottom surface of the interconnect substrate 32. In one example, the windings of the canted coil spring 100 can be inclined in the mating direction as they extend up in the direction from the host substrate 26 toward the interconnect substrate 32. Accordingly, the contact of the canted coil spring 100 with the interconnect substrate 32 and the host substrate 26 can resist movement of the interconnect substrate 32 with respect to the host substrate 26 in the direction opposite the mating direction.

The coil spring assembly 94 can be removed from its position between the interconnect substrate 32 and the host substrate 26 prior to unmating the interconnect substrate from the host module 22. In particular, the deflectable latch finger 40 can be depressed so as to disengage the deflectable latch finger 40 from the latch aperture 42, and the coil spring assembly 94 can be moved in a direction substantially opposite the direction that the latch arm 38 is cantilevered. Next, the interconnect substrate 32 can be unmated from the host module 22. Alternatively, as described above, the canted coil assembly can include the upper and lower plates 96 and 98, respectively, that are configured to bear against the interconnect substrate 32 and the host substrate 26, respectively. Thus, the interconnect substrate 32 can be unmated from the host module 22 without first removing the coil spring assembly 94 from its position between the interconnect substrate 32 and the host substrate 26. Alternatively, the canted coil assembly can include one or more attachment pegs 48, whereby the canted coil assembly is configured to be attached to the host substrate 26 prior to mating the interconnect substrate 32 to the host assembly 22, and further is configured to be removed from the host substrate 26 after the interconnect substrate 32 has been removed from the host module 22.

As described above, the latch 36 of any example described above can include a thermal bridge 60, and vice versa. For instance, the latch 36 of any example described above can include the canted coil spring 100. Referring to FIGS. 24A-24D show the latch 36 described above with respect to FIGS. 6 and 9 integrated with the canted coil assembly 94. As described above, the latch 36 can be monolithic with the housing 102 of the canted coil assembly 94. Further, the latch 36 can define a retention aperture 54 as described above with respect to FIGS. 6 and 8. The at least one thermal support arm 104 can extend along the opening 54 in the horizontal direction, such that the at least one canted coil spring 100 is disposed about at least one thermal support arm 104. For instance, the thermal support arm 104 can be elongate along the lateral direction A. Thus, the canted coil spring 100 can extend about the thermal support arm 104 circumferentially, and can extend along the lateral direction A. When the latch 36 has secured the interconnect substrate 32 to the host substrate 26 in the manner described above with respect to one or both of FIGS. 6 and 9, the canted coil spring 100 can define a conductive thermal path from the interconnect substrate 32 to the host substrate 26 in the manner described above.

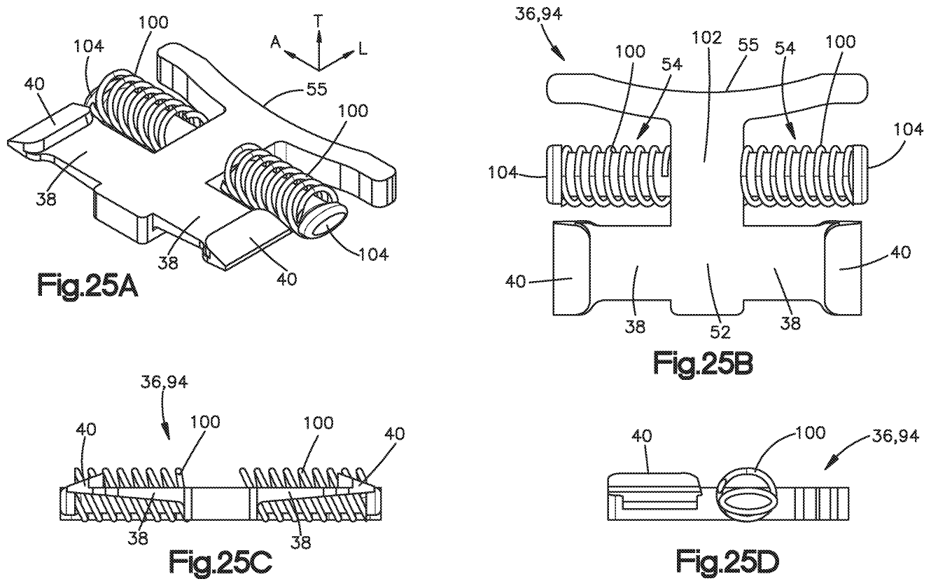

In another example shown in FIGS. 25A-25D, the latch described above with respect to FIG. 7 can be integrated with the canted coil assembly 94. As described above, the latch 36 can be monolithic with the housing 102 of the canted coil assembly 94. Further, the latch 36 can define at least one retention aperture 54 as described above with respect to FIG. 6. In one example, the latch 36 can define first and second retention apertures 54 that are each open to opposed lateral sides of the latch 36. Thus, the thermal support arms 104 can extend away from each other along the lateral direction A in respective different ones of the retention apertures 54. Canted coil springs 100 can surround respective ones of the thermal support arms 104 in the manner described above. First and second latch arms 38 can also extend away from each other along the lateral direction A as described above with respect to FIG. 7. The first and second latch arms 38 can extend into respective ones of the retention apertures 54. The latch arms 38 can thus be oriented substantially parallel to the thermal support arms 104. When the latch 36 has secured the interconnect substrate 32 to the host substrate 26 in the manner described above with respect to FIG. 7, the canted coil spring 100 can define a conductive thermal path from the interconnect substrate 32 to the host substrate 26.

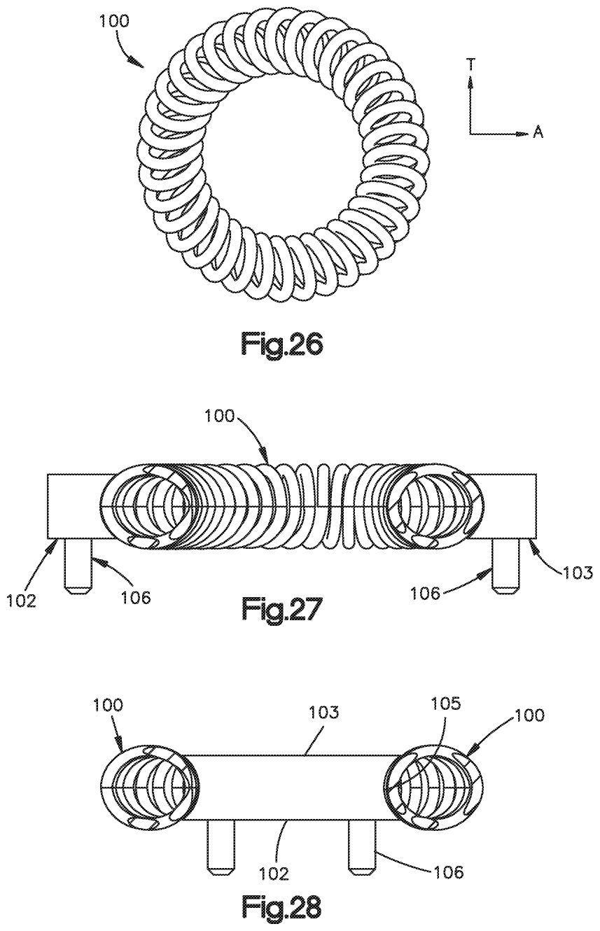

In other embodiments, the canted coil spring 100 may be bent in the horizontal plane so that it is no longer linear, but is circular, elliptical, or some other shape. For instance, as illustrated in FIG. 26, the canted coil spring 100 can be arranged in so as to define a substantially circular shape along the horizontal direction. When used in the thermal bridge 60, the canted coil spring 100 can be seated horizontally on the host substrate 26 such that the coils are sloped with respect to the transverse direction T. Accordingly, the canted coil spring 100 can expand and compress in the transverse direction while maintaining contact with both the interconnect substrate 32 and host substrate 26 as the gap 58 (see FIG. 12) between them varies.

One or more of these bent canted coil springs 100 may be incorporated into a thermal bridge 60 in any suitable manner as desired. For example, several nominally circular canted coil springs may be arranged in a concentric pattern. Further, the thermal support housing 102 can register the bent canted coil spring on the host substrate 26, so it is disposed between the host substrate 26 and the interconnect substrate 32. As illustrated in FIG. 27, the thermal support housing 102, and thus the thermal support body 103, can surround the bent circular canted coil spring 100 in a plane that is defined by the longitudinal direction L and the lateral direction A.

Alternatively, referring to FIG. 28, the thermal support housing 102 can be disposed internal to the circular canted coil spring 100. Thus, the canted coil spring 100 can define an internal opening, and at least a portion of the thermal support housing 102 can be disposed in the opening. The thermal support housing 102 can define at least one concave side surface 105 that nests with the canter spring 100. Thus, it should be appreciated that the thermal support housing 102 can be supported by the canted coil spring 100. The at least one concave side surface 105 can be defined by the thermal support body 103. It should be appreciated, however, that the thermal support housing 102 can be supported by the canted coil spring 100 in any suitable alternative embodiment as desired. The circular canted coil spring 100 can surround the thermal support housing 102, and thus the thermal support body 103, in a plane that is defined by the longitudinal direction L and the lateral direction A. As described above, the thermal support housing 102 may have one or more attachment pegs 48 that can be configured to register or secure the thermal support housing 102 to one or both of the host substrate 26 and the interconnect module 24 with respect to the horizontal direction. It should be appreciated that the thermal support housing 102 of FIGS. 27-28 can be incorporated into the latch 36 as described above with respect to any of FIGS. 1A-11. Otherwise stated, the latch 36 as described above with respect to FIGS. 1-11 can include the thermal support housing 102 and the canted coil spring 100 that is supported by the thermal support housing 102 in any example described herein.

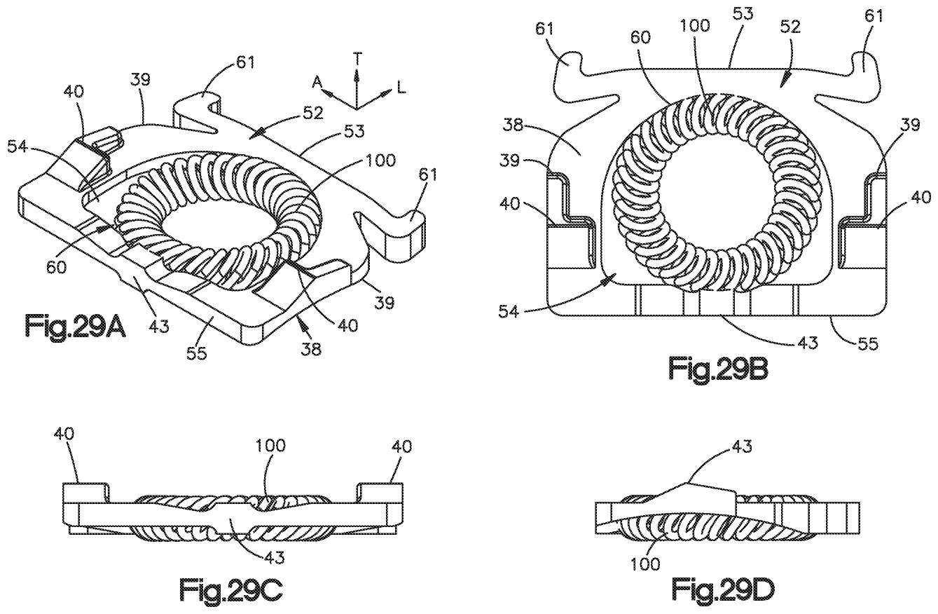

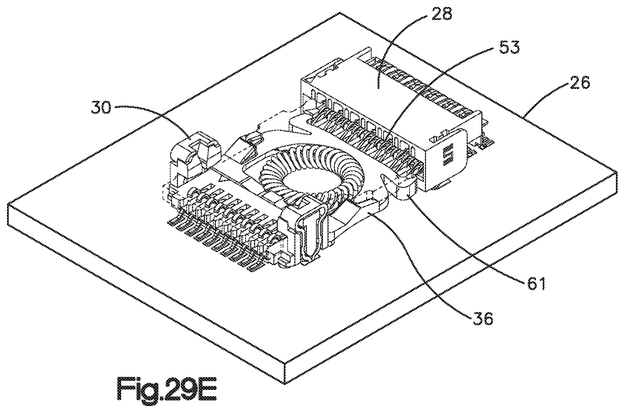

Referring now to FIGS. 29A-29E, the latch 36 can include an integrated canted coil 100 to provide a thermally conductive path in the manner described above. In this example, the latch 36 can define the retention aperture 54 that extends through the latch arm 38. Further, the latch 36 can be cantilevered out from the latch body 52 in the manner described above. The latch 36 can further include first and second latch fingers 40 that extend out with respect to the latch arm 38 in the manner described above. In one example, the latch fingers 40 can be spaced from each other along the lateral direction A. In another example, the latch fingers 40 can be spaced from each other along the longitudinal direction L. For instance, the latch arm 38 can define first and second latch sides 39 that each support a respective one of the latch fingers 40. The latch fingers 40 can extend out from respective ends of the first and second sides 39. The latch arm 38 can further define an end wall 43 that is connected between the first and second sides 39 of the latch arm 38. The latch body 52, and in particular a leg 53 of the latch body 52, the latch sides 39, and the end wall 43 can cooperate so as to define the outer perimeter of the retention aperture 54.

In one example, the sides 39 can extend from the latch body 52 to the end wall 43 along a path that is nonlinear. The sides 39 can be referred to as bridge between the latch body 52 and the end wall 43. Rather, the sides 39 can be curved as it extends along a direction that is perpendicular to the transverse direction T. Thus, the sides 39 can help to maximize the space available for the canted coil 100 that is disposed in the retention aperture 54. The latch arm 38, including the sides 39, can be flexible in the manner described above. Thus, when a sufficient force is applied to the arm 38 along the transverse direction, the arm 38 can flex in response to applied force. Thus, as the interconnect substrate 32 is mated to the host module 22, the fingers 40 can ride along the bottom surface of the interconnect substrate 32. When the interconnect substrate 32 has been mated to the host module 22, the fingers 40 can be received in respective latch apertures of the interconnect substrate as described above.

An inner surface of the latch 36 that defines a portion of the outer perimeter of the retention aperture 54 can be undercut so that the curved surface of the canted coil can nest within the latch 36. The retention aperture can be sized slightly smaller than the relaxed state of the canted coil 100 in a direction between the latch body 52 and the end wall 43. The canted coil 100 can thus be captured so that it stays in place while handling the latch 36. The retention aperture 54 may be slightly larger than the canted coil 100 in the direction between the sides 39, so there is clearance for the canted coil to expand as it is compressed when situated between the interconnect substrate 32 and host substrate 26. The sides 39 can be spaced from each other along the lateral direction A in one example. Thus, the latch body 52 and the end wall 43 can be spaced from each other along the longitudinal direction L. Alternatively, the sides 39 can be spaced from each other along the longitudinal direction L, and the latch body 52 and the end wall 43 can be spaced from each other along the lateral direction A.

The latch body 52 may also include at least one securement member such as a latch hook 61 that extends out from the leg 53. The leg 53 can be elastic and configured to deform as the latch 36 is inserted between the front and rear connectors 28 and 30. The latch body 52 can include first and second hooks 61 that extend out from opposite sides of the leg 53 with respect to the lateral direction A. The hooks 61 may engage complementary features on one of the first and second electrical connectors 28 and 30, such that the latch 36 is secured between the connectors 28 and 30 even when the interconnect substrate 32 has not been mated with the host module 22. This may help facilitate assembly of the interconnect system 20.

As illustrated at FIG. 29E, the latch 36 with integrated thermal bridge 60 of FIGS. 29A-29D can be mounted on the host substrate 26 at a location between the first and second electrical connectors 28 and 30. The leg 53 and hooks 61 can align with complementary features of the first electrical connector 28 so as to prevent the latch 36 from sliding out from under the interconnect module 24 (outline of the transceiver shown in FIG. 29E when the interconnect module 24 is configured as a transceiver). Further, the hooks 61 can secure to complementary securement members 35 of the electrical connector as described above with respect to FIGS. 8A-8B (see also FIG. 13A).

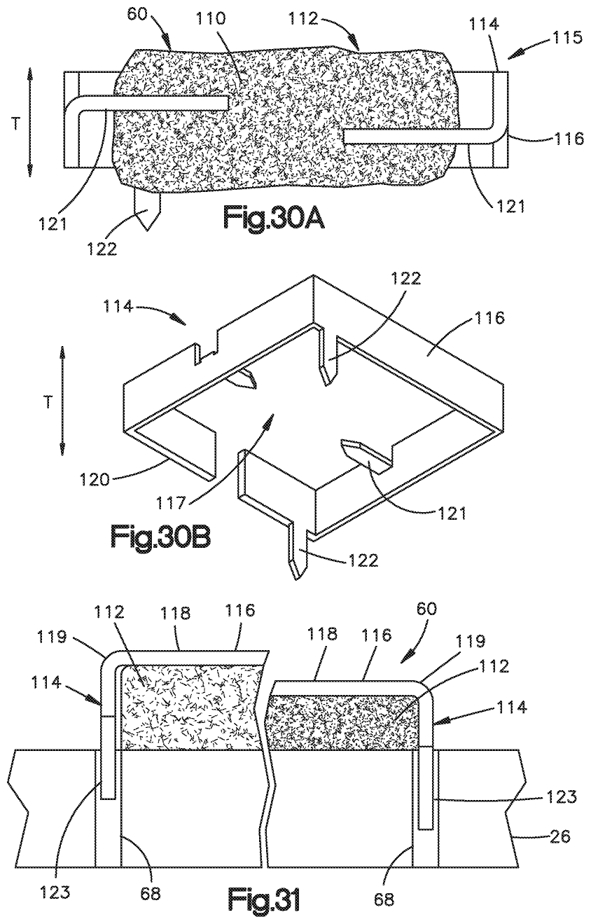

Referring now to FIG. 30A, in yet another example, the thermal bridge 60 can be formed from at least one bent wire 110, such as a plurality of bent wires 110. The bent wires 110 can be compliant and thermally conductive. Further, the bent wires can be randomly oriented. The bent wires 110 can be said to define a thermally conductive fuzz ball 112. The fuzz ball 112 can be compressible in the transverse direction T, and can include a plurality of wires that make mechanical contact with whatever objects that are compressing the fuzz ball 112. Thus, the wires can establish a thermally conductive path from the interconnect substrate 32 to the host substrate 26. It should therefore be appreciated that the thermally conductive spring member 59 of the thermal bridge 60 (see FIG. 15) can be defined by at least one fuzz ball 112.

Referring to FIG. 30B, the thermal bridge 60 can include a fuzz ball retainer 114 that is configured to receive and retain the fuzz ball 112 so as to define a fuzz ball assembly 115. The fuzz ball retainer 114 can include a retainer thermal support body 116 that defines an opening 117 that is configured to retain the fuzz ball 112. The opening 117 can be any shape as desired, including square, circular, rectangular, elliptical, or any other shape. The fuzz ball retainer thermal support body 116 can be configured as a band 120 that extends continuously around a majority of the perimeter of the fuzz ball retainer 114. Thus, the band 120 can define a majority of the opening 117. The band 120 can have a height along the transverse direction that is smaller than the gap 58 between the host substrate 26 and interconnect substrate 32 (see FIG. 14). The fuzz ball 112 can extend both above and below the band 120 along the transverse direction T when the fuzz ball 112 is in its uncompressed state.

The fuzz ball retainer 114 can include at least one retention tab 121 that extends out from the band 120. In particular, the fuzz ball retainer 114 can include first and second retention tabs 121 that assist in securing the fuzz ball 112 in the fuzz ball retainer 114. The retention tabs 121 can be oriented in a plane that includes the longitudinal direction L and the lateral direction A. The retention tabs 121 can be disposed at the same height or at different heights with respect to the transverse direction T. The retention tabs 121 can support the fuzz ball 112 such that the fuzz ball 112 rests on the retention tabs 121. Alternatively, the retention tabs 121 can pierce the fuzz ball 112. The fuzz ball retainer 114 can further include at least one attachment tab 122 that is configured to engage a corresponding attachment member of the host substrate 26, so as to attach the fuzz ball retainer to one or both of the host substrate 26 and the interconnect substrate 32, or limit movement of the fuzz ball retainer with respect to one or both of the host substrate 26 and the interconnect substrate 32. For instance, the fuzz ball retainer 114 can include first and second attachment tabs 122. The corresponding attachment member can be configured as an aperture along the transverse direction T in one or both of the host substrate 26 and the interconnect substrate 32 that is configured to receive a respective one of the attachment tabs 122. Engagement of the attachment tabs 122 with the corresponding attachment member of the host substrate 26 can cause the retainer 114 to be located on the host substrate 26 with respect to one or both of the longitudinal direction L and the lateral direction A.

When the fuzz ball assembly 115 is installed in the gap 58 between the host substrate 26 and interconnect substrate 32, the fuzz ball 112 is compressed in the transverse direction T. Thus, the top surface of the fuzz ball 112 makes mechanical contact with the bottom surface of the interconnect substrate 32, and the bottom surface of the fuzz ball 112 makes mechanical contact with the top surface of the host substrate 26. Heat is conducted from the interconnect substrate 32 to the host substrate 26 along the conductive thermal path that is defined by the at least one wire 110 alone or in combination with the retainer 114. Thus, the fuzz ball retainer can be thermally conductive as desired.

In the embodiments shown above in FIGS. 30A-30B, the fuzz ball retainer 114 can be configured to retain the fuzz ball 112 that makes direct contact with the host substrate 26 and interconnect substrate 32 when it is inserted in the gap between the host substrate 26 and interconnect substrate 32. In other embodiments, the fuzz ball retainer 114 can be configured to retain a plurality of fuzz balls 112. Thus, it can be said that the fuzz ball retainer 114 is configured to retain at least one fuzz ball 112.

Further, as illustrated in FIG. 31, the at least one fuzz ball 112 retained by the fuzz ball retainer 114 can make direct mechanical contact with one of the host substrate 26 and the interconnect substrate 32, and the fuzz ball retainer 112 can make direct mechanical contact with the other of the host substrate 26 and the interconnect substrate 32. For instance, the fuzz ball retainer 114 can be configured as a cup 116 having an internal void that is configured to support the at least one fuzz ball 112. In some examples, the cup 116 can define a base 118 that defines a resting surface for the fuzz ball 112. The cup 116 can be constructed as described above with respect to the cup 64 illustrated in FIG. 15. As an alternatively to the fuzz balls 112, the retainer 114 can alternatively retain elastic thermally conductive members that can be configured as a thermal gap pad as described above with respect to FIG. 16.

Thus, the cup 116 can include a cup body 119 that defines the base 118, and at least one projection 123, such as a plurality of projections 123, that extends from the cup body 119. The projections 123 can extend from the cup body 119 along the transverse direction T. The projections 123 can be configured to be inserted into respective mounting apertures 68 in the host substrate 26. In one example, the mounting apertures 68 can be configured as slots, and the thermal bridge can be slid into position after the interconnect substrate 32 has been mated with the first and second electrical connectors 28 and 30. In particular, the projections 123 can slide along the slot as the thermal bridge 60 is installed. Alternatively, the apertures 68 can be configured as through-holes, and the thermal bridge 60 may be positioned on the host substrate 26, such that the projections 123 extend through the through-holes, prior to mating the interconnect substrate 32 with the first and second electrical connectors 28 and 30.

While the thermal bridge 60 can be mounted to the host substrate 26 in one example, the thermal bridge 60 can alternatively be mounted to the interconnect substrate 32 if desired. Thus, while the mounting apertures 68 extend into or through the host substrate 26 in one example, the mounting apertures 68 can alternatively extend into or through the interconnect substrate 32. For instance, the cup 116 can include projections 123 that extend into mounting apertures of at least one of the host substrate 26 and the interconnect substrate 32, so as to position the thermal bridge 60 between the interconnect substrate 32 and the host substrate 26.

As described above, the at least one fuzz ball 112 can be compressible along the transverse direction T. Thus, when the thermal bridge 60 is positioned between the interconnect substrate 32 and host substrate 26, the fuzz ball 112 can compress along the transverse direction T. In particular, the base 118 of the cup body 119 can apply a compressive force F against the fuzz ball 112 when the cup 116 is mounted to the at least one of the interconnect substrate 32 and the host substrate 26. The top surface of the cup 116, which can be defined by the base 118, can be in robust mechanical contact with the bottom surface of the interconnect substrate 32. Simultaneously, the bottom surface of the fuzz ball 112 can be in robust mechanical contact with the top surface of the host substrate 26. Thus, the fuzz ball 112 can be compressed between the base 118 of the cup 116 and the host substrate 26 along the transverse direction T. Further, the top surface of the fuzz ball 112 can be in robust mechanical contact with the cup body 119. Alternatively, the cup 116 can be configured such that a bottom surface of the cup 116, which can be defined by the base 118, is in robust mechanical contact with the top surface of the host substrate 26, and the top surface of the fuzz ball 112 can be in robust mechanical contact with the bottom surface of the interconnect substrate 32. Thus, the fuzz ball 112 can be compressed along the transverse direction T by base 118 of the cup 116 and the interconnect substrate 32.

The bottom surface of the fuzz ball may make contact with the top surface of the host substrate 26. The surface of the cup 116 that makes contact with the bottom surface of the interconnect substrate 32 can be substantially flat. When the at least one fuzz ball 112 is in the compressed state, the wires 110 that form the fuzz ball 112 are more closely packed than when the fuzz ball 112 is in the uncompressed state. The fuzz ball wires 110 can be elastically deformed during compression, so that the compressed wires 110 provide a force along the transverse direction T that urges the cup 116 against the one of the interconnect substrate 32 and the host substrate 26 when the fuzz ball 112 is in its compressed state. Furthermore, it is recognized that the projections 123 can be configured to ride in the mounting apertures 68 along the vertical direction. The projections 123 can also be sized smaller than the mounting apertures 68 along the horizontal direction. Accordingly, the cup 116 can be movable along the transverse direction, and can also tilt so as to conform to minor deviations in parallelism between the host substrate 26 and the interconnect substrate 32 while maintaining the base 118 of the cup in surface contact with the interconnect substrate 32.

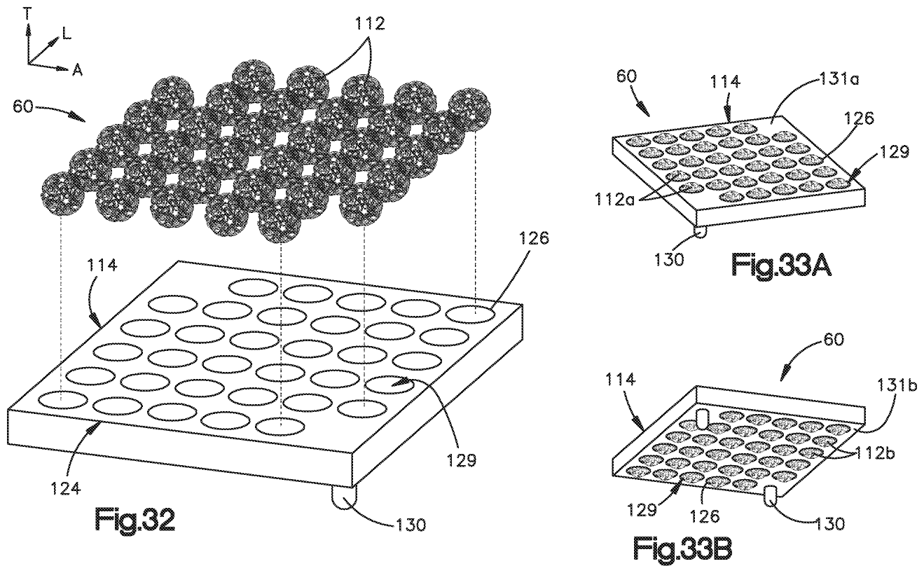

Referring now to FIG. 32, the fuzz ball retainer 114 can be configured to retain a plurality of fuzz balls 112 so as to define the thermal bridge 60 in another example. In this example, the thermal bridge 60 includes any suitable number of fuzz balls 112 arranged in a grid 124. While 34 fuzz balls 112 are illustrated, the number of fuzz balls 112 can vary as desired. Further, while the grid 124 can be rectangular in shape, it should be appreciated that the grid 124 can define any suitable alternative shape as desired. In particular the fuzz ball retainer 114 can define a plurality of cups 126 that are arranged so as to define the grid 124. Each cup 126 is configured to retain at least one of the fuzz balls 112. The cups 126 can include one or more retention features that can assist in retain the fuzz ball 112 ball in the respective cups 126. Alternatively, the fuzz balls 112 can be retained in the respective cups 126 by sizing the cups 126 to be smaller than the fuzz balls 112 in their uncompressed state in at least at one location of the cups 126. For instance, pockets 129 defined by the cups 126 that receive the fuzz balls 112 can have at least a region having a smaller cross-sectional dimension in a plane that is defined by the longitudinal direction L and the lateral direction A, that is less than the cross-sectional dimension of the fuzz balls 112 in the plane when the fuzz balls 112 are in their uncompressed state. In one example, the pockets 129 can have a necked-down region that is smaller than the fuzz balls 112 so as to prevent the fuzz balls 112 from falling out of the pockets 129. The necked-down region can be disposed at mid depth along the pockets 129 along the transverse direction T, or at any suitable alternative location in the pockets 129.

The fuzz ball retainer 114 can further include at least one attachment member that is configured to attach to one of the host substrate 26 and the interconnect substrate 32. For instance, the fuzz ball retainer 114 can include at least one attachment peg 130 configured to engage complementary attachment structure of one of the host substrate 26 and the interconnect substrate 32. The complementary attachment structure can be configured as attachment apertures that are configured to receive the attachment pegs 130. The attachment pegs 130 can be received by attachment apertures of the host substrate 26 in one example. Thus, the fuzz ball retainer 114 can compress the fuzz balls 112 against the host substrate 26. The bottom surfaces of the fuzz balls 112 therefore make mechanical contact with the top surface of the host substrate 26. The top surface of the fuzz ball retainer 114 can make mechanical contact with the bottom surface of the interconnect substrate 32. Thus, the conductive thermal path can be defined from the interconnect substrate 32 through the fuzz ball retainer 114 and the fuzz balls 112 to the host substrate 32.

In another example, the attachment pegs 130 can be received by attachment pegs 130 apertures of the interconnect substrate 32. Thus, the fuzz ball retainer 114 can compress the fuzz balls 112 against the interconnect substrate 32. The top surfaces of the fuzz balls 112 therefore make mechanical contact with the bottom surface of the interconnect substrate 32. The bottom surface of the fuzz ball retainer 114 can make mechanical contact with the top surface of the host substrate 26. Thus, the conductive thermal path can be defined from the interconnect substrate 32 through the fuzz balls 112 and the fuzz ball retainer 114 to the host substrate 26.

It is recognized that the fuzz balls 112 can be elastically compressible along the transverse direction so as to maintain reliable contact with the host substrate and the interconnect substrate, even when the fuzzballs 112 do not make contact to both the host substrate and the interconnect substrate simultaneously, such as when the cup does not define a through hole, and thus defines a base 118 or other support structure for the fuzzballs 112.

The fuzz ball retainer 114 can define any suitable thickness along the transverse direction T as desired. In one example, the thickness can range from approximately 1.0 mm to approximately 2.5 mm. For instance, the thickness can be approximately 1.27 mm. The grid 124 can define any suitable first center-to-center distance of adjacent pockets 129 along the lateral direction A. The first center-to-center distance can be constant along the grid 124. Alternatively, the first center-to-center distance can vary along the grid 124. The grid 124 can define a second center-to-center distance of adjacent pockets 129 along the longitudinal direction L. The second center-to-center distance can be constant along the grid 124. Alternatively, the second center-to-center distance can vary along the grid 124. The first and second center-to-center distances can be equal to each other. Alternatively, the first and second center-to-center distances can be different than each other. In one example, the first and second center-to-center distances can range from approximately 0.75 mm to approximately 3 mm. For instance, the first and second center-to-center distances can be approximately 1.27 mm. The grid 124 can define any suitable dimension along each of the lateral direction A and the longitudinal direction L. The dimension can range from approximately 4 mm to approximately 12 mm. In one example, the dimension can be approximately 8 mm. The fuzz ball retainer 114 may be sized so that it does not extend beyond the footprint of the interconnect substrate 32 or host substrate 26. As illustrated in FIG. 32, the fuzz ball retainer cups 126 can be arranged equidistantly in a regular grid defined by main perpendicular axes. It should be appreciated, of course, that the fuzz ball retainer cups 126 can alternatively be arranged in any suitable regular geometric pattern as desired, including but not limited to a hexagonal pattern. Alternatively still, the fuzz ball retainer cups 126 can be disposed in a random arrangement. Thus, it should be recognized that the fuzz ball retainer cups 126, and thus the fuzz balls, can have a density that can be substantially consistent across the fuzz ball retainer 114 in a plane that is perpendicular to the transverse direction T. Alternatively, the density can vary across the fuzzball retainer 114 in a plane that is perpendicular to the transverse direction T as needed to provide a desired thermal load transfer, cost, contact force, and the like.

The fuzz balls 112 can be constructed as desired. In one example, the fuzz balls 112 can be constructed as a Fuzz Button® interposers commercially available from Custom Interconnects, LLC having a place of business in Centennial, Colo. Alternatively, the thermal bridge as described herein can include a CIN::APSE® thermal device commercially available from Bel Fuse Inc., having a place of business in Jersey City, N.J.

Referring now to FIGS. 33A-33B, the cups 126 can be disposed on both the top and bottom surfaces 131a and 131b, respectively of the fuzz ball retainer 113. In this example, a first group 112a of fuzz balls 112 disposed in the cups 126 at the top surface 131a of the fuzz ball retainer 114 makes mechanical contact with the bottom surface of the interconnect substrate 32 in their compressed state. A second group 112b of fuzz balls 112 disposed in the cups 126 at the bottom surface 131b of the fuzz ball retainer 114 makes contact with the top surface 131a of the host substrate 26 in their compressed state. Thus, the conductive thermal path can be defined from the interconnect substrate 32, through the first group 112a of fuzz balls 112, the fuzz ball retainer 114, and the second group 112b of fuzz balls, to the host substrate 26. Each of the fuzz balls 112 can apply any suitable contact force against at least one of the interconnect substrate 32 and the host substrate 26 when the fuzz balls 112 are in their compressed state. The fuzz balls 112 can apply a cumulative force in a range from approximately 300 gram force (go to approximately 1500 gf. For instance, the cumulative force applied by the fuzz balls can be approximately 708 gf.

In some embodiments, the cups in the fuzz ball retainer 114 can define one or more through holes. In this embodiment, at least one fuzz ball 112 retained in the fuzz ball retainer 114 may extend through the at least one through hole both below the bottom of the fuzz ball retainer 114 and above the top of the fuzzball retainer 114. In one example, a fuzz ball 112 can extend through the fuzz ball retainer 114. When the fuzz ball retainer 114 is positioned between the interconnect substrate 32 and host substrate 26 the same fuzzball may contact both the interconnect substrate 32 and host substrate 26. Alternatively, an upper fuzz ball 112 can extend into the upper through hole and contact the interconnect substrate 32, and a lower fuzz ball 112 can extend into the lower through hole and contact the host substrate 26. The upper and lower fuzz balls 112 can be in thermal communication with each other through the fuzz ball retainer 114.

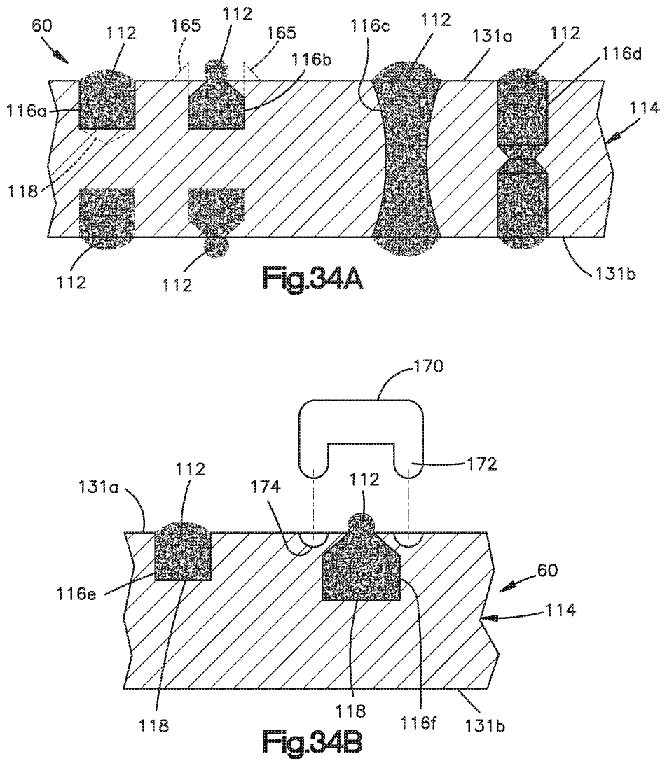

Referring now to FIGS. 34a-34b, one or more up to all of the cups 116 can assume any suitable geometry and configuration as shown, or any alternative geometry suitable for retaining the fuzz balls 112. For instance, in one example, one or more up to all of the cups 125 can be configured as a first cup 116a that can extend from one or both of the top and bottom surfaces 131a and 131b toward the opposed. The first cup 116a can be generally cylindrical or other shape that defines a rectangular vertical cross-section. In one example, the first cup 125a can terminate in the retainer 114 so as to define a base 118. The first cup 116a can have a relief cut at its base 118. The fuzz ball 112 disposed in the first cup 116a can be compressed against the at least one side wall of the first cup 116a.

Alternatively or additionally, one or more up to all of the cups 116 can be configured as a second cup 116b constructed as described above with the first cup 116a, however with an inwardly tapered opening 160 to the internal void. The opening can taper inwardly as it extends to an outer surface of the retainer 114. The outer surface of the retainer 114 can be defined by the top surface 131a or the bottom surface 131b. In this regard, the tapered opening can provide retention for the fuzz ball 112 in the internal void. A portion of the fuzz ball 121 can extend out from the cup 125 so as to contact one of the host substrate and the interconnect substrate. The beveled opening can be defined by cut outs 165 from the material of the retainer 114 that are folded over upon themselves such that they extend into the internal void and define the tapered opening.

Alternatively or additionally, one or more up to all of the cups 116 can be configured as a third cup 116c that can define a through hole from the top surface 131a to the bottom surface 131b. The third cup 116c can define an hourglass shape that provides a retention force against the fuzz ball 112 disposed therein. The fuzz ball 112 can extend out with respect to each of the top surface 131a and the bottom surface 131b of the retainer 114. The hourglass shape can be smooth as illustrated with respect to the third cup 116c, or can include adjacent adjoining angled surfaces 162 as illustrated with respect to a fourth cup 116d. One or more up to all of the cups 116 can be configured as a third cup 116d.

Alternatively or additionally, one or more up to all of the cups 116 can be configured as a fifth cup 116e that can be configured as described above with respect to the first cup 116a, but with a flat base 118. In this regard, any of the cups 116 that terminate in the retainer can have any suitable base 118 as desired.

Alternatively or additionally, one or more up to all of the cups 116 can be configured as a six cup 116f that can have a tapered opening as described above with respect to the second cup 116b. However, the tapered opening can be defined by a stamping operation in which a stamp tool 170 is brought against the top or bottom surface 131a or 131b, respectively, of the fuzz ball retainer 114 so as to deform the material of the retainer 114, thereby creating the tapered opening. In one example, the stamp tool 10 can include at least one stamp arm 172 that is brought against the retainer 114 so as to create an indentation 174 that moves material of the retainer 114 into the internal void, thereby creating the tapered opening.

In all the previously described examples, the forces exerted by the thermal bridge 60 can be distributed along the host substrate 26 and interconnect substrate 32. The force distribution can be equal in some examples. In one aspect, it can be desirable for the thermal bridge 60 to exert a large force against the host substrate 26 and interconnect substrate 32. This force can be provided by the elastic compression of the thermal bridge. A large elastic force will improve the thermal contact between the thermal bridge 60 and the substrates 26 and 32. In another aspect, it can be desirable to prevent the elastic force from being excessive. For instance, if the elastic force is too large, it will be difficult to slide the interconnect substrate 32 over the thermal bridge 60 when mating the interconnect substrate 32 to the host module 22. Alternatively, if the interconnect substrate 32 is mated to the host module 22 prior to installing the thermal bridge 60, then it can be difficult to slide the thermal bridge 60 between the interconnect substrate 32 and the host substrate 26. Also, excessive force will tend to lift contacts pads on the interconnect substrate 32 off their mating electrical contacts on the second electrical connector 30 and/or put undue stresses on the front electrical connector 28. It is recognized, of course, that the excessive force can be offset by an external member that applies a counterforce downward toward the host board, such as from a cold plate that contacts the top of the transceiver.

It is believed that that a total elastic force of the thermal bridge 60 in its compressed state in the range of approximately 3 Newtons (N) to approximately 6 N can provide adequate force for reliable thermal contact with the host substrate 26 and the interconnect substrate 32, without being too large. It should be appreciated that the outward force exerted by the thermal bridge 60 to the substrates 26 and 32 may be more than approximately 6 N or less than approximately 3 N depending on several factors, such as the size of the contact region between the thermal bridge 60 and the substrates 26 and 32.

In any of the examples described above, the thermal bridge 60 can undergo both plastic (i.e., inelastic) deformation and elastic deformation. For example, the thermal bridge 60 can undergo one or both of elastic deformation and plastic deformation when it is inserted in the gap between the interconnect substrate 32 and host substrate 26. The elastic properties of the thermal bridge may be chosen so as to maintain a relatively constant contact force between the thermal bridge 60 and the substrates 26 and 32 as the gap 58 between the substrates 26 and 32 varies.

Initial testing has indicated that a factor of two reduction in a temperature difference between a VCSEL (Vertical Cavity Surface Emitting Laser) mounted on the interconnection substrate 36 and the host substrate 26 is achievable using some of the thermal bridges 60 described herein.

While the present disclosure has generally been described in the context of an interconnect substrate 32, it should be appreciated that the latch and thermal bridge system and method described herein is not so limited. The interconnect substrate 32 may be used in an optical transceiver, optical receiver, or optical transmitter. More generally, the latch and/or thermal bridge can be used to secure and/or provide a low impedance thermal path between any suitable daughter substrate, respectively, such as a PCB, and a host substrate 26, where the host substrate has a front and rear electrical connector mounted on it and the two connectors are separated in a longitudinal direction, which is the daughter substrate insertion direction into the first electrical connector 28. As described above, the daughter substrate can be configured as an interconnect substrate in one example. More generally still, the latch and/or thermal bridge can be used to secure and/or provide a low impedance thermal path, respectively, between any two roughly planar and parallel surfaces facing each other and where the gap between the two surfaces can vary over time.

Further while the present disclosure has been generally described in the context of the host module 22 including the first and second electrical connectors 28 and 30, it should be appreciated that the latch 36 and thermal bridge 60 may be used in situations where two substantially planar substrates are to be secured to each other, and one of the substrates has two longitudinally separated mating regions. The planar substrates can be oriented parallel to each other. The mating regions limit motion in the transverse direction T, which is normal to the planar surfaces of the first and second substrate. The latch, 36 and thermal bridge 60 can fit between the two substrates and limit motion in the longitudinal direction L so that the two substrates are secured together. The latch 36 may fit between the first and second connectors 28 and 30 so that it does not extend beyond the footprint of either of the first and second substrates. The latch 36 and thermal bridge 60 can be elastically deformed when the latch 36 is disposed between the two substrates. An attachment member of the latch 36 can engage with a complementary attachment feature of the second substrate to limit relative motion of the substrates in the longitudinal direction L, thereby securing the two substrates together.

It should be appreciated that the illustrations and discussions of the embodiments shown in the figures are for exemplary purposes only, and should not be construed limiting the disclosure. One skilled in the art will appreciate that the present disclosure contemplates various embodiments. For instance, while the present disclosure has been generally described in the context of using two separate first and second connectors 28 and 30 that define front and rear connectors, respectively, it should be appreciated that these connectors may form a unitary structure which is mounted to the host substrate 26. As such rather than there being two connectors, there is a single connector that has two longitudinally separated mating or connection regions. Alternatively, the first and second connectors 28 and 30 can be spaced from each other along the lateral direction A. Further, it should be appreciated that the host assembly 22 can include more than the first and second electrical connectors 28 and 30, and can have additional contact regions configured to establish an electrical connection with the interconnect module for the purpose of data transmission or some other purpose. Additionally, it should be understood that the concepts described above with the above-described embodiments may be employed alone or in combination with any of the other embodiments described above. It should be further appreciated that the various alternative embodiments described above with respect to one illustrated embodiment can apply to all embodiments as described herein, unless otherwise indicated.

1. A latch for securing a daughter substrate to a host module having first and second electrical connectors that are mounted on a host substrate, the latch comprising:
a latch body having a latch base and a latch finger that is supported by the latch base;
wherein the latch is sized to fit between the daughter substrate and host substrate, such that the latch finger engages a corresponding latch engagement member of at least one of the daughter substrate and the host substrate to secure the daughter substrate to the host module after the daughter substrate has been mated to the first and second electrical connectors.

2. The latch as recited in claim 1, further comprising an attachment peg configured to attach to the other of the daughter substrate and the host substrate prior to engaging the latch finger with the latch engagement member.

3. The latch as recited in claim 2, wherein the attachment peg and the latch finger extend out from opposed surfaces of the latch body.

4. The latch as recited in claim 1, further comprising a latch arm that extends out from the latch base, and the latch finger extends out from the latch arm.

5. The latch as recited in claim 4, wherein the latch arm is resiliently deflectable away from the one of the daughter substrate and the host substrate.

6. (canceled)

7. The latch as recited in claim 1, further comprising a thermal bridge that defines a thermally conductive path from the daughter substrate to the host substrate when the latch has secured the daughter substrate to the host module.

8. (canceled)

9. The latch as recited in claim 1, wherein the first and second electrical connectors are spaced from each other in a longitudinal direction, and the latch is configured to be disposed between the two electrical connectors.

10. The latch as recited in claim 1, wherein the daughter substrate comprises an interconnect substrate that supports at least one of an optical transmitter, and an optical receiver, and an optical transceiver.

11. The latch as recited in claim 1, further comprising a fixed latch finger that extends out from latch base and configured to be received in a respective aperture of the one of the daughter substrate and the host substrate.

12-16. (canceled)

17. A latch configured to secure a daughter substrate to a host module having first and second electrical connectors mounted on a host substrate such that the daughter substrate and the host substrate are spaced from each other along a transverse direction, wherein the latch is sized to fit between the daughter substrate and the host substrate along the transverse direction, wherein the latch does not extend past a footprint of the daughter substrate on the host substrate in a plane that is oriented perpendicular to the transverse direction.

18. The latch as recited in claim 17, further comprising a latch body having a latch base and a latch finger that is supported by the latch base, wherein the latch finger is configured to engage a corresponding latch engagement member of at least one of the daughter substrate and the host substrate to secure the daughter substrate into the host module.

19. The latch as recited in claim 18, wherein the latch further comprises a latch arm that extends out from the latch base, and the latch finger extends out from the latch arm.

20. (canceled)

21. The latch as recited in claim 20, wherein the latch arm is resiliently deflectable along the transverse direction with respect to the latch base.

22. The latch as recited in claim 18, further comprising an attachment peg configured to attach to the other of the daughter substrate and the host substrate prior to engaging the latch finger with the latch engagement member.

23. The latch as recited in claim 22, wherein the attachment peg and the latch finger extend out from respective surfaces of the latch body that are opposite each other along the transverse direction.

24. The latch as recited in claim 17, further comprising a thermal bridge that is configured to define a thermally conductive path from the daughter substrate to the host substrate when the latch has secured the daughter substrate to the host module.

25. A latch configured to secure a daughter substrate to a host module after the daughter substrate has mated with first and second electrical connectors that are mounted on a host substrate of the host module, wherein the latch includes a thermal bridge that establishes a thermally conductive path from the daughter substrate to the host substrate when the latch has secured the daughter substrate to the host module.

26. The latch as recited in claim 25, further comprising a latch body having a latch base and a latch finger that is supported by the latch base, wherein the latch finger is configured to engage a corresponding latch engagement member of at least one of the daughter substrate and the host substrate to secure the daughter substrate into the host module.

27. The latch as recited in claim 26, wherein the latch further comprises a latch arm that extends out from the latch base, and the latch finger extends out from the latch arm.

28. The latch as recited in claim 27, wherein the finger extends out from a distal end of the latch arm.

29. The latch as recited in claim 27, wherein the latch arm is resiliently deflectable along a transverse direction with respect to the latch base.

30. The latch as recited in claim 26, further comprising an attachment peg configured to attach to the other of the daughter substrate and the host substrate prior to engaging the latch finger with the latch engagement member.

31. (canceled)

32. The latch as recited in claim 25, wherein at least a portion up to all of the latch comprises a thermally conductive material.

33. The latch as recited in claim 32, wherein the thermally conductive material comprises one of graphite aluminum, aluminum, copper, beryllium copper, and graphite copper.

34. The latch as recited in claim 25, wherein the thermal bridge is compressible.

35-46. (canceled)

47. A thermal bridge comprising:
a thermally conductive spring member that is configured to be positioned between a host printed circuit board and a daughter substrate such that the thermal bridge provides a thermally conductive heat transfer path from the daughter substrate to the host printed circuit board.

48-67. (canceled)

68. A system comprising:
the thermal bridge as recited in claim 47, and
a latch having a latch body and at least one latch finger, wherein the latch body supports the thermal bridge.

69. (canceled)

70. A latch comprising:
a latch body defining a top surface and a bottom surface opposite the top surface along a transverse direction, wherein the latch body comprises a latch base; and
a movable latch finger that is supported by the latch base, wherein the movable latch finger is movable with respect to the latch body along the transverse direction.

71. The latch as recited in claim 69, wherein the latch body further comprises a flexible arm that extends out from the latch base, and is configured to flex in a direction that causes the deflectable finger to move along the transverse direction, wherein the latch finger extends out from the flexible arm.

72. The latch as recited in claim 71, wherein the flexible arm extends out from the latch base along a direction that is substantially perpendicular to the transverse direction when the latch arm is unflexed.

73. The latch as recited claim 70, further comprising a fixed finger opposite the deflectable finger.

74. The latch as recited in claim 70, wherein the latch is sized to be disposed in a gap that extends between 1 host substrate and an interconnect substrate along the transverse direction.

75. The latch as recited in claim 70, further comprising a thermal bridge supported by the latch body.

76. The latch as recited in claim 70, wherein the latch body defines an aperture that receives a thermal bridge.

77-91. (canceled)

92. A latch configured to secure a daughter substrate to a host module having first and second electrical connectors that are mounted on a host substrate after the daughter substrate has been mated with the host module along a longitudinal direction, the latch comprising:
a latch body having a latch base, a movable first latch finger that is supported by the latch base, and a second latch finger supported by the latch base and spaced from the first latch finger along a lateral direction that is perpendicular to the longitudinal direction,
wherein the latch is sized to fit between the daughter substrate and host substrate, such that the first latch finger engages a corresponding latch engagement member of at least one of the daughter substrate and the host substrate to secure the daughter substrate to the host module after the daughter substrate has been mated to the first and second electrical connectors, and
and the second finger is configured to be inserted into a notch of at least one of the daughter substrate and the host substrate.

93-96. (canceled)
